(19) United States
(12) Patent Application Publication
(10) Pub. No.: US 2026/0107814 A1
(43) Pub. Date: Apr. 16, 2026

(54) ELECTRONIC DEVICE

(71) Applicant: ROHM CO., LTD., Kyoto-shi (JP)

(72) Inventors: Hiroyuki SHINKAI, Kyoto-shi (JP); Hiroki MIYAZAKI, Kyoto-shi (JP)

(21) Appl. No.: 19/422,062

(22) Filed: Dec. 16, 2025

Related U.S. Application Data
(63) Continuation of application No. PCT/JP2024/019857, filed on May 30, 2024.

(30) Foreign Application Priority Data
Jun. 22, 2023 (JP) 2023-102475

(51) Int. Cl. H10W 72/00; H10W 74/10

(52) U.S. Cl. CPC H10W 72/823; H10W 72/01; H10W 74/111

(57) ABSTRACT

An electronic device comprises a substrate, an electronic element, a columnar portion and a sealing resin. The substrate includes an insulating layer having an insulating layer obverse surface facing a first side in a thickness direction and an insulating layer reverse surface, and a conductive portion exposed from the insulating layer obverse surface and the insulating layer reverse surface. The electronic element includes an element body having an element obverse surface facing the insulating layer obverse surface in the thickness direction, and electrodes disposed on the element obverse surface. The electrodes are electrically bonded to the conductive portion. The columnar portion projects from the conductive portion toward the first side in the thickness direction and has electrical conductivity. The sealing resin covers the insulating layer obverse surface, the electronic element, and the columnar portion.

### TECHNICAL FIELD

The present disclosure relates to an electronic device.

### BACKGROUND ART

Conventionally, electronic devices including an electronic element have been proposed in various forms. For example, JP-A-2021-93454 discloses a semiconductor device as an example of a conventional electronic device. The semiconductor device described in JP-A-2021-93454 includes a substrate having a substrate obverse surface, a semiconductor element disposed on the substrate obverse surface, a wiring portion, a substrate metal layer, and a sealing resin. The sealing resin covers the substrate obverse surface and the semiconductor element.

### BRIEF DESCRIPTION OF THE DRAWINGS

FIG. 1 is a plan view of an electronic device according to a first embodiment.

FIG. 2 is a partial plan view of the electronic device in the plan view of FIG. 1.

FIG. 3 is a partial plan view of the electronic device in the plan view of FIG. 2.

FIG. 4 is a front view of the electronic device according to the first embodiment.

FIG. 5 is a bottom view of the electronic device according to the first embodiment.

FIG. 6 is a left-side view of the electronic device according to the first embodiment.

FIG. 7 is a right-side view of the electronic device according to the first embodiment.

FIG. 8 is a cross-sectional view taken along line VIII-VIII in FIG. 1.

FIG. 9 is an enlarged partial cross-sectional view of a portion of FIG. 8.

FIG. 10 is a cross-sectional view of one step of a method of manufacturing the electronic device according to the first embodiment, which corresponds to the cross section of FIG. 8.

FIG. 11 is a cross-sectional view of one step of a method of manufacturing the electronic device according to the first embodiment, which corresponds to the cross section of FIG. 8.

FIG. 12 is a cross-sectional view of one step of a method of manufacturing the electronic device according to the first embodiment, which corresponds to the cross section of FIG. 8.

FIG. 13 is a cross-sectional view of one step of a method of manufacturing the electronic device according to the first embodiment, which corresponds to the cross section of FIG. 8.

FIG. 14 is a cross-sectional view of one step of a method of manufacturing the electronic device according to the first embodiment, which corresponds to the cross section of FIG. 8.

FIG. 15 is a cross-sectional view of one step of a method of manufacturing the electronic device according to the first embodiment, which corresponds to the cross section of FIG. 8.

FIG. 16 is a cross-sectional view of one step of a method of manufacturing the electronic device according to the first embodiment, which corresponds to the cross section of FIG. 8.

FIG. 17 is a cross-sectional view of one step of a method of manufacturing the electronic device according to the first embodiment, which corresponds to the cross section of FIG. 8.

FIG. 18 is a cross-sectional view of one step of a method of manufacturing the electronic device according to the first embodiment, which corresponds to the cross section of FIG. 8.

FIG. 19 is a cross-sectional view of one step of a method of manufacturing the electronic device according to the first embodiment, which corresponds to the cross section of FIG. 8.

FIG. 20 is a cross-sectional view of one step of a method of manufacturing the electronic device according to the first embodiment, which corresponds to the cross section of FIG. 8.

FIG. 21 is a cross-sectional view of one step of a method of manufacturing the electronic device according to the first embodiment, which corresponds to the cross section of FIG. 8.

FIG. 22 is a cross-sectional view of one step of a method of manufacturing the electronic device according to the first embodiment, which corresponds to the cross section of FIG. 8.

FIG. 23 is a cross-sectional view of one step of a method of manufacturing the electronic device according to the first embodiment, which corresponds to the cross section of FIG. 8.

FIG. 24 is a cross-sectional view of one step of a method of manufacturing the electronic device according to the first embodiment, which corresponds to the cross section of FIG. 8.

FIG. 25 is a cross-sectional view of a first variation of an electronic device according to the first embodiment.

FIG. 26 is a cross-sectional view of a second variation of an electronic device according to the first embodiment.

FIG. 27 is a cross-sectional view of a third variation of an electronic device according to the first embodiment.

FIG. 28 is a plan view of a fourth variation of an electronic device according to the first embodiment.

FIG. 29 is a cross-sectional view taken along line XXIX-XXIX in FIG. 28.

FIG. 30 is a plan view of a fifth variation of an electronic device according to the first embodiment.

FIG. 31 is a plan view of a sixth variation of an electronic device according to the first embodiment.

FIG. 32 is a partial plan view of an electronic device according to a second embodiment.

FIG. 33 is a cross-sectional view taken along line XXXIII-XXXIII in FIG. 32.

FIG. 34 is an enlarged partial cross-sectional view of a portion of FIG. 33.

FIG. 35 is a cross-sectional view of one step of a method of manufacturing the electronic device according to the second embodiment, which corresponds to the cross section of FIG. 34.

FIG. 36 is a cross-sectional view of one step of a method of manufacturing the electronic device according to the second embodiment, which corresponds to the cross section of FIG. 34.

FIG. 37 is a cross-sectional view of one step of a method of manufacturing the electronic device according to the second embodiment, which corresponds to the cross section of FIG. 34.

FIG. 38 is a cross-sectional view of one step of a method of manufacturing the electronic device according to the second embodiment, which corresponds to the cross section of FIG. 34.

FIG. 39 is a cross-sectional view of one step of a method of manufacturing the electronic device according to the second embodiment, which corresponds to the cross section of FIG. 34.

FIG. 40 is a cross-sectional view of one step of a method of manufacturing the electronic device according to the second embodiment, which corresponds to the cross section of FIG. 34.

FIG. 41 is an enlarged partial cross-sectional view of a first variation of an electronic device according to the second embodiment.

FIG. 42 is a cross-sectional view of one step of a method of manufacturing the first variation of the electronic device according to the second embodiment, which corresponds to the cross section of FIG. 41.

FIG. 43 is a cross-sectional view of one step of a method of manufacturing the first variation of the electronic device according to the second embodiment, which corresponds to the cross section of FIG. 41.

FIG. 44 is a cross-sectional view of one step of a method of manufacturing the first variation of the electronic device according to the second embodiment, which corresponds to the cross section of FIG. 41.

### DETAILED DESCRIPTION:

Embodiments of the present disclosure will be described with reference to the accompanying drawings. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the expression “An object A (or the material thereof) contains a material C” includes “the object A (or the material thereof) is made of a material C” and “the object A (or the material thereof) is mainly composed of a material C”. Also, the expression “A surface A faces (a first side or a second side) in a direction B” is not limited to the situation where the angle of the surface A to the direction B is 90° and includes the situation where the surface A is inclined with respect to the direction B.

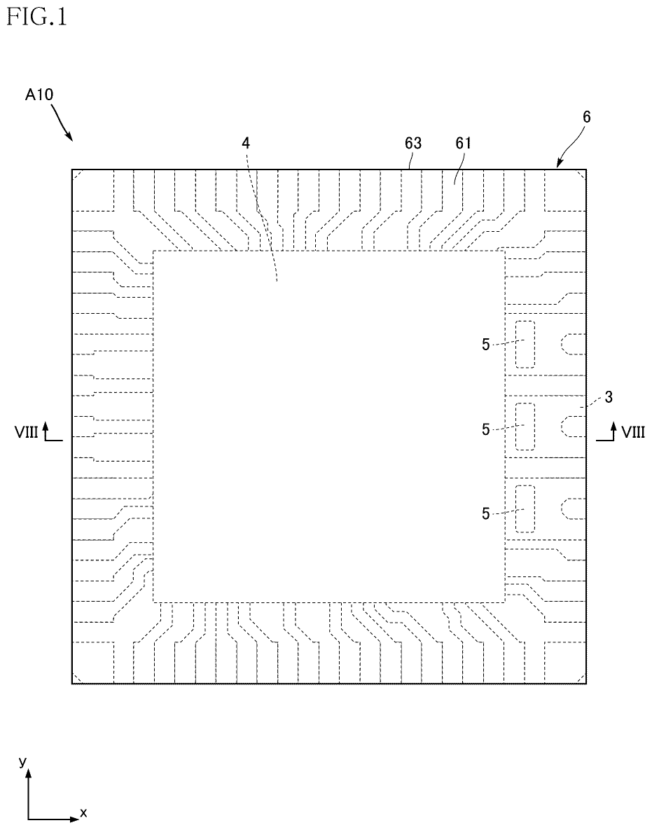

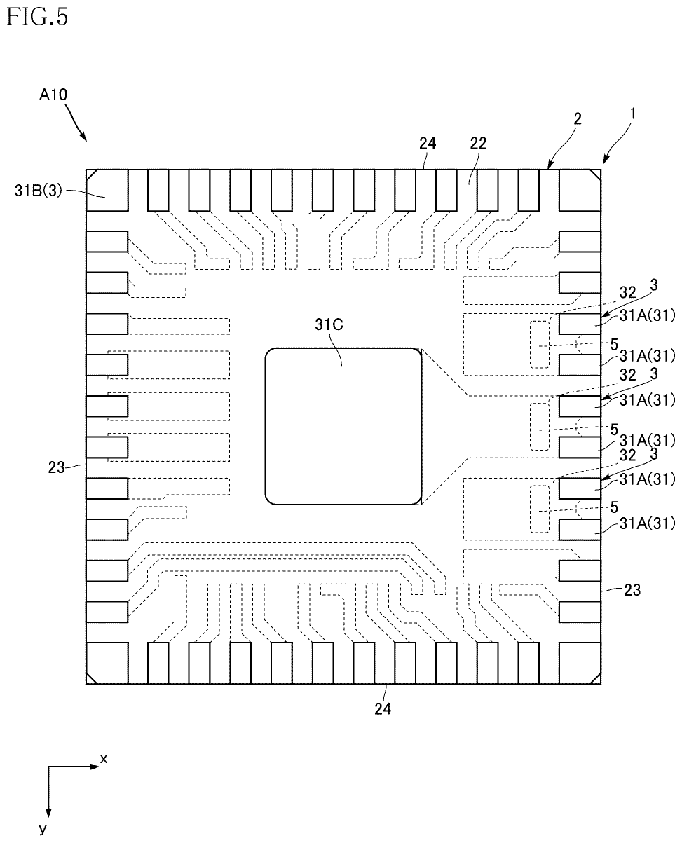

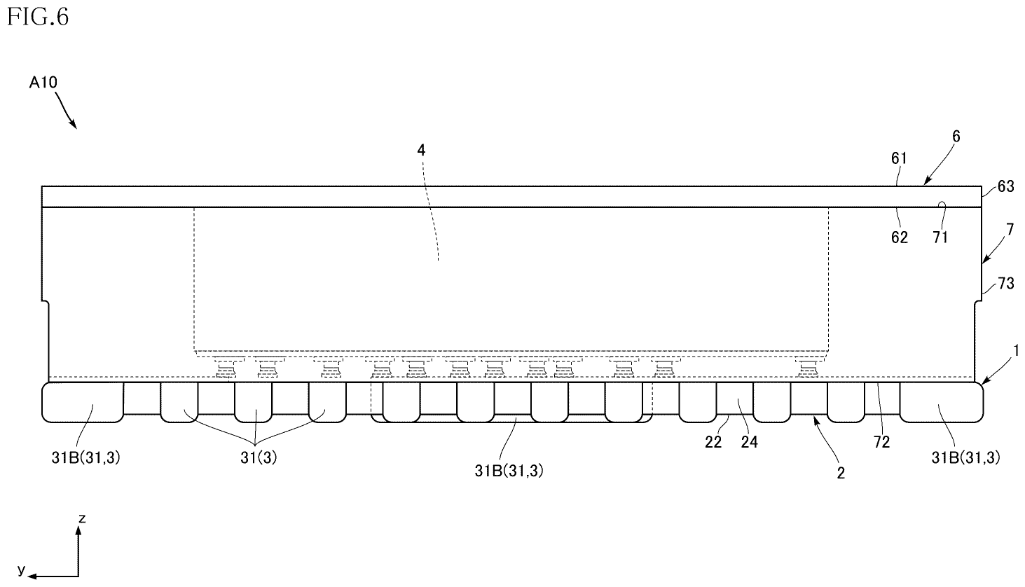

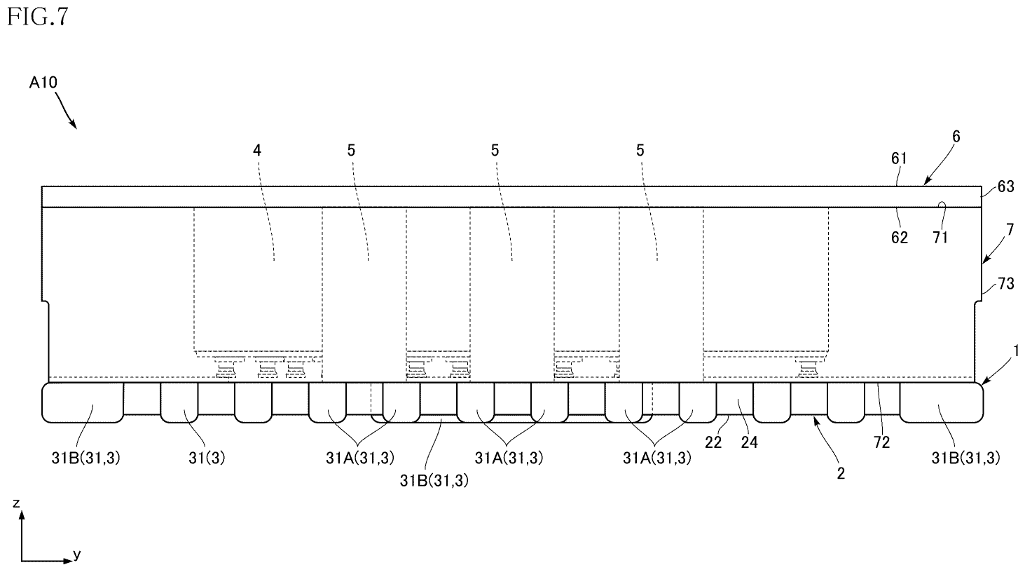

FIGS. 1 to 9 show an electronic device A10 according to a first embodiment. The electronic device A10 includes an insulating layer 2, a conductive portion 3, an electronic element 4, a columnar portion 5, and a sealing resin 7. In the present embodiment, a metal layer 6 is further provided for an auxiliary function. The electronic device A10 is a device to be surface-mounted on a wiring board of electronic equipment and electric vehicles and the like. The electronic device A10 is of a leadless package type, specifically a Quad Flat Non-Leaded (QFN) package. The electronic device A10 is rectangular in planar view.

For convenience of explanation, reference is made to a thickness direction z, a first direction x and a second direction y, which are orthogonal to one another. The thickness direction z corresponds to a thickness direction of the electronic device A10. In the following description, one side in the thickness direction z may be referred to as upper, and may correspond to a first side of the present disclosure. The other side in the thickness direction z may be referred to as lower, and may correspond to a second side of the present disclosure. Note that the terms such as “upward”, “downward”, “upper”, “lower”, “upper surface” and “lower surface” indicate the relative positional relationship of each component in the thickness direction z, and do not necessarily define the relationship with respect to the direction of gravity. The term “planar view” means as viewed in the thickness direction z.

In the present embodiment, the electronic element 4 is a semiconductor element, for example, an integrated circuit such as an LSI. Alternatively, the electronic element 4 may be a voltage-control element such as a Low Drop Out (LDO), an amplifying element such as an operational amplifier, or a discrete element such as a transistor or a diode. The electronic element is rectangular in planar view. The electronic element 4 is connected to bonding portions 49. The electronic element 4 overlaps with the bonding portions 49 in planar view.

The electronic element 4 includes an element body 40. The element body 40 is mainly composed of, for example, a semiconductor material or a metal material. The element body 40 has an element obverse surface 41, an element reverse surface 42, and element side surfaces 43, 44. The element obverse surface 41 and the element reverse surface 42 are spaced apart from each other in the thickness direction z. The element obverse surface 41 and the element reverse surface 42 face away from each other in the thickness direction z. The element side surfaces 43, 44 are located between the element obverse surface 41 and the element reverse surface 42 in the thickness direction z. In the present embodiment, each of the element side surfaces 43, 44 faces the first direction x or the second direction y. The element obverse surface 41 and the element side surfaces 43, 44 are covered with the sealing resin 7.

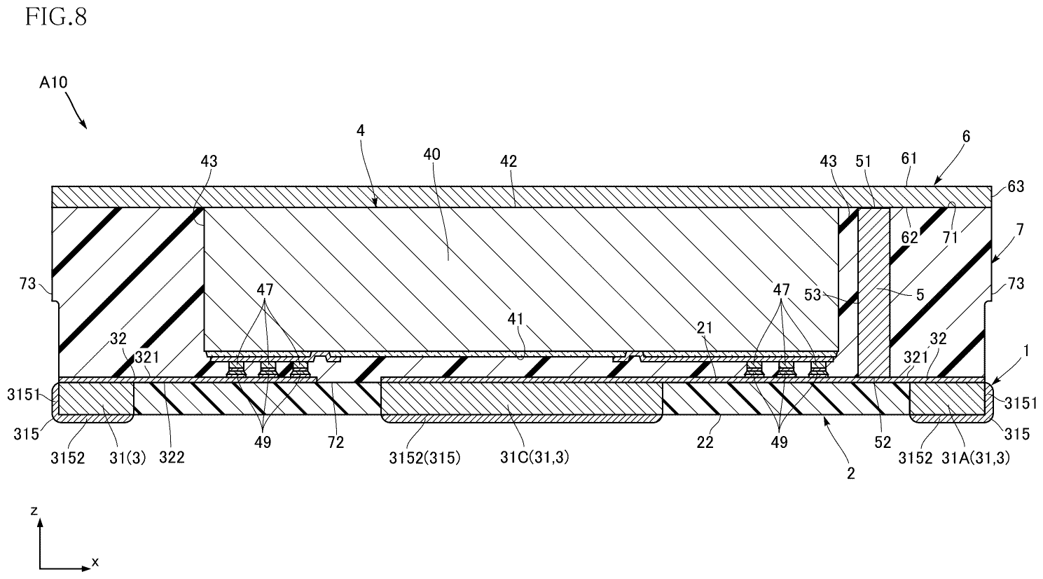

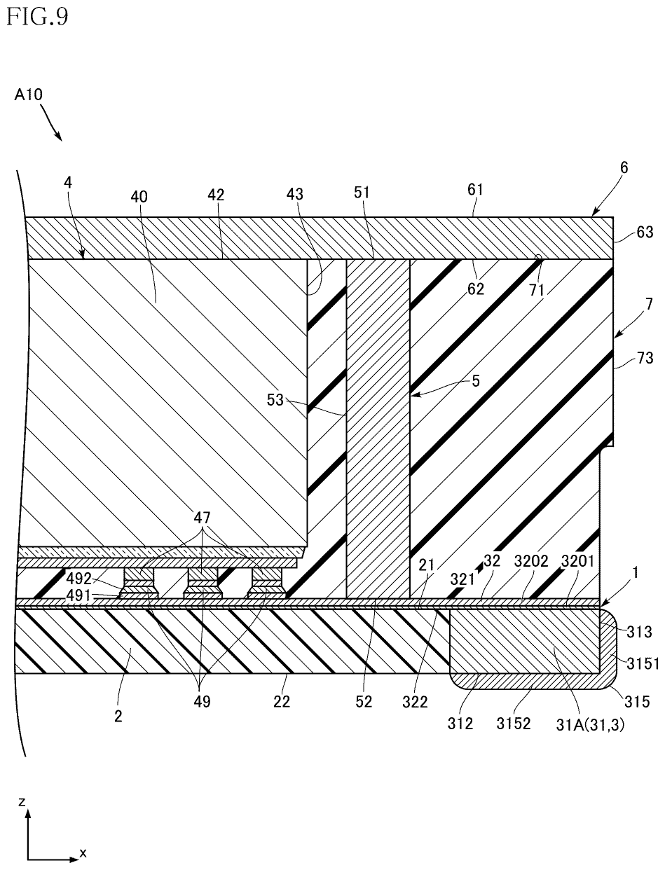

As shown in FIGS. 8 and 9, the electronic element 4 includes the element body 40 and a plurality of electrodes 47. For example, in a case where the electronic element 4 is an LSI, the element body 40 contains a semiconductor material. The electrodes 47 are electrically connected to a circuit (not shown) within the element body 40. The element obverse surface 41 corresponds to a lower surface (a surface facing downward in the thickness direction z) of the element body 40. In the example shown in FIGS. 8 and 9, each electrode 47 projects downward in the thickness direction z from the element obverse surface 41. However, each electrode 47 may be flush with the element obverse surface 41, or may be recessed upward in the thickness direction z from the element obverse surface 41. The element obverse surface 41 is partially covered with an insulating film (not shown), and each electrode 47 is exposed from the insulating film. The insulating film contains, for example, polyimide or polybenzoxazole. Each electrode 47 contains a metal material. The metal material includes aluminum, silver, gold, or copper. Each electrode 47 may have a single-layer structure or a laminated structure of a plurality of layers.

The substrate 1 is a support for the electronic element 4. The substrate 1 includes the insulating layer 2 and the conductive portion 3.

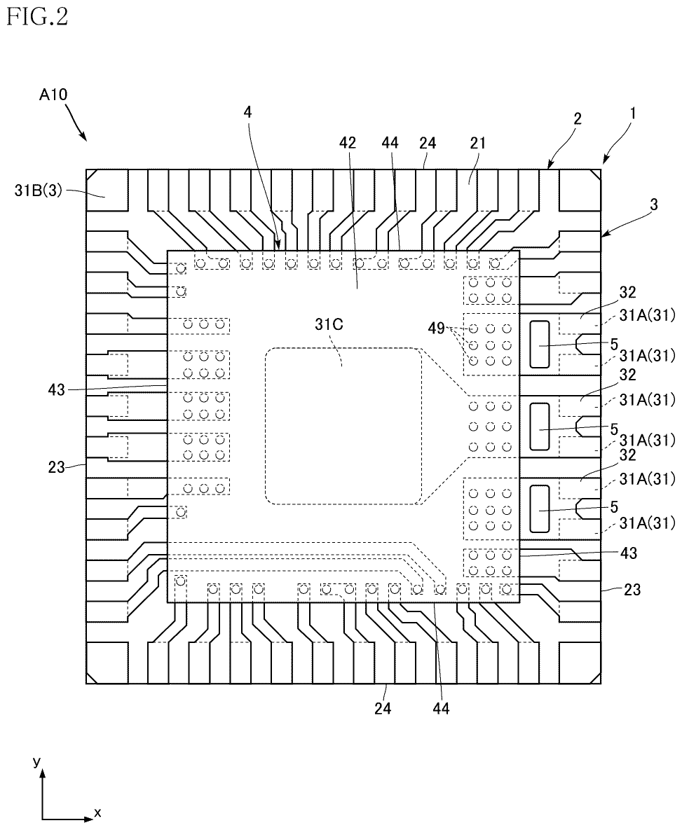

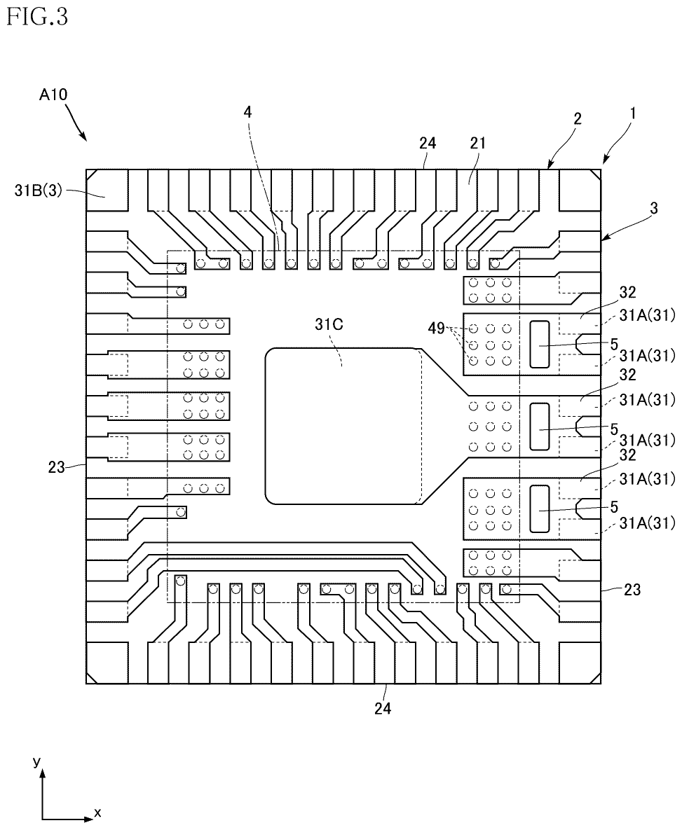

As shown in FIGS. 2 and 6 to 9, the insulating layer 2 supports the electronic element 4. The insulating layer 2 contains, for example, a resin material. The resin material is the same as the sealing resin 7, but may be different from the sealing resin 7. Instead of a resin material, the insulating layer 2 may contain monocrystalline intrinsic semiconductor (for example, silicon (Si)), glass, or a ceramic. As shown in FIGS. 2 and 3, the insulating layer 2 is rectangular in planar view. A thickness (dimension along the thickness direction z) of the insulating layer 2 is not particularly limited and is, for example, in a range from 30 μm to 300 μm.

As shown in FIGS. 2 to 8, the insulating layer 2 includes an insulating layer obverse surface 21, an insulating layer reverse surface 22, two insulating layer side surfaces 23, and two insulating layer side surfaces 24. The insulating layer obverse surface 21 and the insulating layer reverse surface 22 are spaced apart from each other in the thickness direction z. The insulating layer obverse surface 21 and the insulating layer reverse surface 22 face away from each other in the thickness direction z. The insulating layer obverse surface 21 is an upper surface of the insulating layer 2, and the insulating layer reverse surface 22 is a lower surface of the insulating layer 2. The insulating layer obverse surface 21 faces the electronic element 4. When the electronic device A10 is mounted on a circuit board, the insulating layer reverse surface 22 faces the circuit board. In the present embodiment, the insulating layer 2 is covered with the sealing resin 7, and the insulating layer reverse surface 22 is exposed from the sealing resin 7. As shown in FIGS. 2 to 8, each insulating layer side surface 23 and each insulating layer side surface 24 are interposed between the insulating layer obverse surface 21 and the insulating layer reverse surface 22. Each insulating layer side surface 23 and each insulating layer side surface 24 include an upper end in the thickness direction z connected to the insulating layer obverse surface 21 and a lower end in the thickness direction z connected to the insulating layer reverse surface 22. The two insulating layer side surfaces 23 are a pair of side surfaces facing away from each other in the x direction. The two insulating layer side surfaces 24 are a pair of side surfaces facing away from each other in the y direction, and are each in contact with the two insulating layer side surfaces 23.

The bonding portions 49 bond the conductive portion 3 and the electronic element 4. Each bonding portion 49 is a conductive bonding material. The bonding portion 49 includes a barrier metal 491 and a solder layer 492. The solder layer 492 contains a flux and an alloy including tin (Sn) (e.g., an Sn-silver (Ag) alloy). The composition of the bonding portion 49 is not limited to these examples and can be modified within a reasonable range.

Each bonding portion 49 is interposed between one of the electrodes 47 of the electronic element 4 and the conductive portion 3, and bonds them. Accordingly, the electronic element 4 is electrically connected to the conductive portion 3 via the bonding portions 49.

The conductive portion 3 is a conductor disposed within the electronic device A10. The conductive portion 3 includes a plurality of terminal portions 31 and a plurality of wiring portions 32.

As shown in FIG. 9, each wiring portion 32 includes a wiring portion obverse surface 321 and a wiring portion reverse surface 322. The wiring portion obverse surface 321 and the wiring portion reverse surface 322 are spaced apart from each other in the thickness direction z. The wiring portion obverse surface 321 and the wiring portion reverse surface 322 face away from each other. The wiring portion obverse surface 321 is an upper surface of the wiring portion 32, and the wiring portion reverse surface 322 is a lower surface of the wiring portion 32. The wiring portion 32 may have a seed layer 3201 and a plating layer 3202. The seed layer 3201 is formed on the insulating layer obverse surface 21 and is in contact with the insulating layer 2. The seed layer 3201 contains, for example, titanium. The plating layer 3202 is laminated on the seed layer 3201. The plating layer 3202 contains, for example, copper. Alternatively, the wiring portion 32 may be a single layer constituted of a conductor. A thickness (dimension along the thickness direction z) of the wiring portion 32 is not particularly limited and is, for example, in a range from 10 μm to 100 μm.

The terminal portions 31 penetrate the insulating layer 2 in the thickness direction z. Each terminal portion 31 is connected to a corresponding one of the wiring portions 32 and to each of a plurality of conductor films 315, and electrically connects the wiring portion 32 and the conductor film 315. The terminal portion 31 contains, for example, a metal material. The metal material is not particularly limited and is, for example, copper.

A plan-view shape of each terminal portion 31 is not particularly limited and is rectangular in the illustrated example. In the illustrated example, an upper surface (terminal portion obverse surface 311) of each terminal portion 31 is flush with the insulating layer obverse surface of the insulating layer 2.

Each terminal portion 31 has a terminal portion obverse surface 311, a terminal portion reverse surface 312, and a terminal portion side surface 313. The terminal portion obverse surface 311 faces upward in the thickness direction z. The terminal portion reverse surface 312 faces downward in the thickness direction z. The terminal portion side surface 313 includes an upper end in the thickness direction z connected to the terminal portion obverse surface 311, and a lower end in the thickness direction z connected to the terminal portion reverse surface 312. The terminal portion reverse surface 312 may be exposed from the insulating layer reverse surface 22 of the insulating layer 2. As shown in FIG. 9, the terminal portion reverse surface 312 may be flush with the insulating layer reverse surface 22.

The conductor films 315 are films of conductors electrically connected to the respective wiring portions 32 and exposed to the outside of the electronic device A10. Each conductor film 315 includes a lower conductor film 3152 that is in contact with the corresponding terminal portion reverse surface 312. Each conductor film 315 may include a side conductor film 3151 that is in contact with a corresponding one of the terminal portion side surfaces 313. The conductor films 315 connect the electronic device A10 and a circuit board when the electronic device A10 is mounted on the circuit board. At least one of the conductor films 315 projects from the insulating layer reverse surface 22. Each conductor film 315 is formed, for example, by electroless plating. At least one of the conductor films 315 may comprise a plurality of metal layers laminated in the order of an Ni layer, a palladium (Pd) layer, and a gold (Au) layer from the side in contact with the terminal portion 31. As another configuration, at least one of the conductor films 315 may be constituted of a plurality of metal layers laminated in the order of an Ni layer and an Au layer, or of a Cu layer, an Ag layer, and an Sn layer, from the side in contact with a corresponding one of the terminal portion 31. Materials and forming methods of the conductor films 315 are not limited to these examples.

As shown in FIGS. 2, 3, and 5, the terminal portions 31 include a plurality of ground terminal portions 31A, a plurality of corner terminal portions 31B, and a center terminal portion 31C. The ground terminal portions 31A are each connected to a ground line. In the illustrated example, the ground terminal portions 31A are arranged along the second direction y. The corner terminal portions 31B are disposed at the four corners of the insulating layer 2, respectively. The center terminal portion 31C is disposed so as to overlap with the electronic element 4 in planar view.

A plurality of columnar portions 5 are disposed in a direction where the insulating layer obverse surface 21 faces with respect to the insulating layer 2. Each columnar portion 5 is disposed on a wiring portion 32 of corresponding one of the conductive portions 3 and projects upward in the thickness direction z from the wiring portion 32. A plan-view shape of each columnar portion 5 is not particularly limited, and in the illustrated example, it has a rectangular shape elongated in the second direction y. Each columnar portion 5 has electrical conductivity and contains, for example, a metal material. The metal material is, for example, copper. Each columnar portion 5 is formed, for example, by electrolytic plating. A size of each columnar portion 5 in the thickness direction z may be greater than, or may be smaller than, a thickness of the electronic element 4. In the present embodiment, at least one of the columnar portions 5 is formed so as to penetrate the resin obverse surface 71 in the thickness direction z. In the present embodiment, each columnar portion 5 has a cross section taken on a plane orthogonal to the thickness direction z, whose shape and size are substantially constant along the thickness direction z; however, the present disclosure is not limited thereto. Either or both of the shape and the size of a cross section orthogonal to the thickness direction z of at least one of the columnar portions 5 may be different at respective portions along the thickness direction z.

Each columnar portion 5 has a columnar portion obverse surface 51, a columnar portion reverse surface 52, and a columnar portion side surface 53. The columnar portion obverse surface 51 faces upward in the thickness direction z. The columnar portion reverse surface 52 faces downward in the thickness direction z. The columnar portion side surface 53 includes an upper end in the thickness direction z connected to the columnar portion obverse surface 51, and a lower end in the thickness direction z connected to the columnar portion reverse surface 52. As shown in FIG. 9, the terminal portion reverse surface 312 may be flush with the insulating layer reverse surface 22.

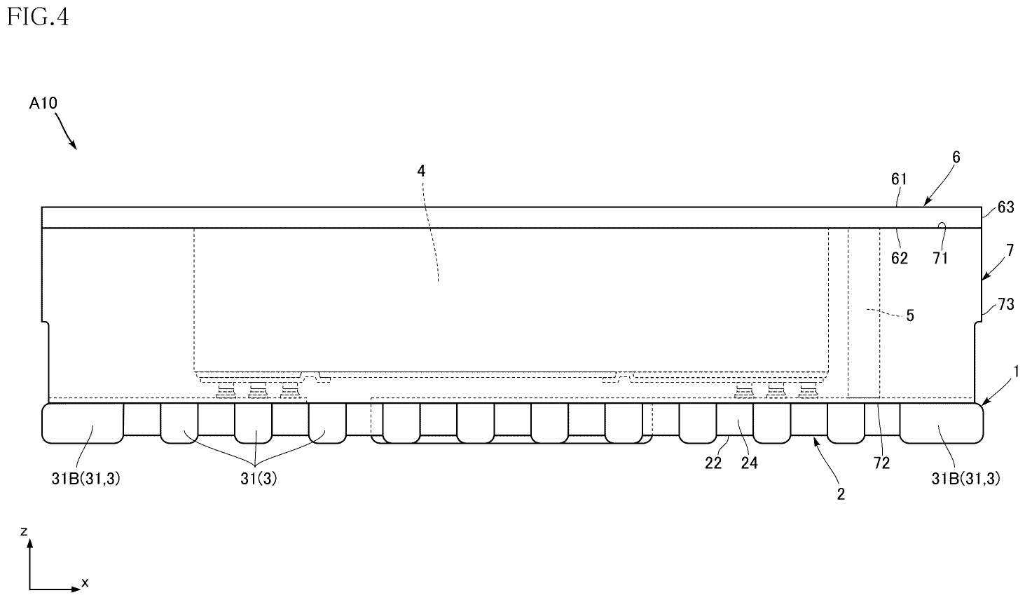

The metal layer 6 is disposed on the element reverse surface 42. The metal layer 6 may have a metal layer obverse surface 61, a metal layer reverse surface 62, and a metal layer side surface 63. The metal layer obverse surface 61 faces upward in the thickness direction z. The metal layer reverse surface 62 faces downward in the thickness direction z. The metal layer side surface 63 includes an upper end in the thickness direction z connected to the metal layer obverse surface 61, and a lower end in the thickness direction z connected to the metal layer reverse surface 62. As shown in FIGS. 4, 8, and 9, the metal layer 6 is disposed on the electronic element 4 and on at least one of the columnar portions 5.

The sealing resin 7 is a synthetic resin mainly composed of a black epoxy resin, for example. The sealing resin 7 may include a filler such as silica mixed into the epoxy resin. As shown in FIGS. 1, 2, 4, 6, and 7, the sealing resin 7 covers the electronic element 4 and the columnar portions 5. The sealing resin 7 also covers the bonding portions 49, the wiring portions 32, and a part of the insulating layer 2. The sealing resin 7 is formed on the insulating layer obverse surface 21. The sealing resin 7 is rectangular in planar view. A thickness (dimension along the thickness direction z) of the sealing resin 7 is not particularly limited and is, for example, in a range from 200 μm to 1200 μm. As shown in FIGS. 1, 2, 4, 6, and 7, the sealing resin 7 has a resin obverse surface 71, a resin reverse surface 72, and a plurality of resin side surfaces 73.

As shown in FIGS. 4, 6, and 7, the resin obverse surface 71 and the resin reverse surface 72 are spaced apart from each other in the thickness direction z. The resin obverse surface 71 and the resin reverse surface 72 face away from each other in the thickness direction z. The resin obverse surface 71 faces, in the thickness direction z, the same direction as each of the element reverse surface 42 of the electronic element 4 and the insulating layer obverse surface 21. In the present embodiment, a part of the electronic element 4 is disposed at the resin reverse surface 72. The resin reverse surface 72 faces, in the thickness direction z, the same direction as each of the element obverse surface 41 of the electronic element 4 and the insulating layer reverse surface 22. The resin reverse surface 72 is in contact with the insulating layer obverse surface 21. The resin reverse surface 72 has unevenness depending on a shape of at least one of the wiring portions 32. As shown in FIGS. 4, 6, and 7, each of the resin side surfaces 73 is interposed between the resin obverse surface 71 and the resin reverse surface 72 in the thickness direction z and is connected to these surfaces. As shown in FIGS. 1 and 2, the resin side surfaces 73 include one facing one side in the first direction x, one facing the other side in the first direction x, one facing one side in the second direction y, and one facing the other side in the second direction y.

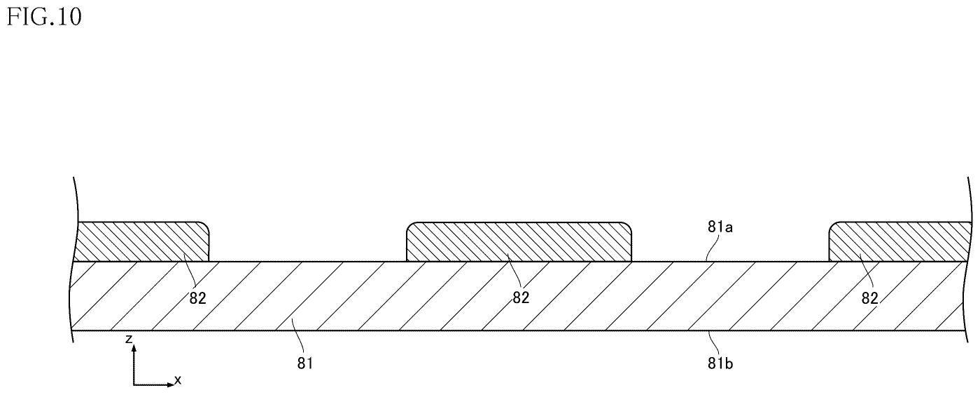

Next, with reference to FIGS. 10 to 24, an example of a method of manufacturing the electronic device A10 will be described. Each of FIGS. 10 to 24 is a cross-sectional view showing one step in the method of manufacturing the electronic device A10. These cross-sectional views correspond to FIG. 8.

First, as shown in FIG. 10, a support substrate 81 is prepared, and a plurality of column bodies 82 are formed on the support substrate 81. The support substrate 81 contains, for example, a monocrystalline intrinsic semiconductor material. The semiconductor material is, for example, Si. In the preparing of the support substrate 81, a silicon wafer may be prepared as the support substrate 81. The support substrate 81 has a support substrate obverse surface 81a and a support substrate reverse surface 81b facing away from each other in the thickness direction z. The column bodies 82 are formed, for example, by the following steps. First, a seed layer is formed on the support substrate obverse surface 81a. The seed layer is formed, for example, by a sputtering method. Then, a resist is patterned on the seed layer, and the column bodies 82 are formed by electrolytic plating. Thereafter, the resist layer and an unnecessary part of the seed layer are removed. Through these steps, the column bodies 82 are formed on the support substrate obverse surface 81a of the support substrate 81. A specific shape and size of each column body 82 are not particularly limited.

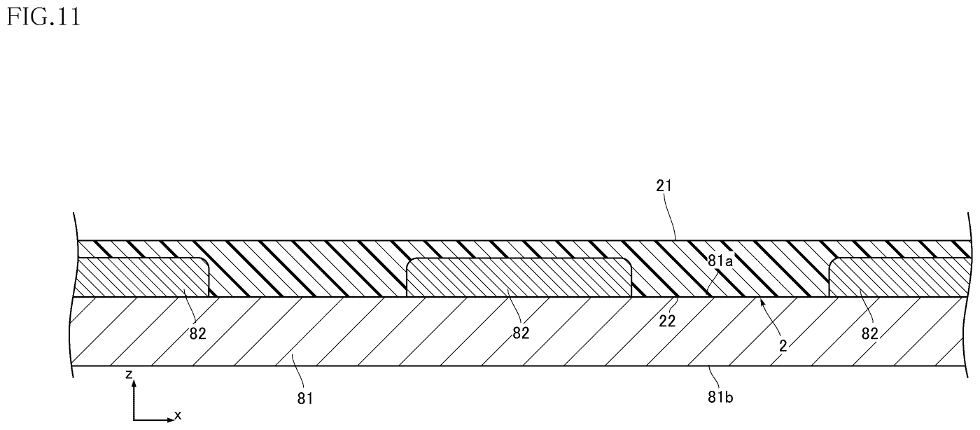

Next, as shown in FIG. 11, the insulating layer 2 is formed on the support substrate obverse surface 81a so as to cover the column bodies 82. The insulating layer 2 is a synthetic resin mainly composed of a black epoxy resin, for example. The insulating layer 2 is formed, for example, by molding. As the insulating layer 2, an insulating resin material other than the synthetic resin may be used. The insulating layer 2 has the insulating layer obverse surface 21 and the insulating layer reverse surface 22 facing away from each other in the thickness direction z. The insulating layer obverse surface 21 faces the same direction as the support substrate obverse surface 81a, and the insulating layer reverse surface 22 faces the support substrate obverse surface 81a. In the forming of the insulating layer 2, the column bodies 82 are completely covered.

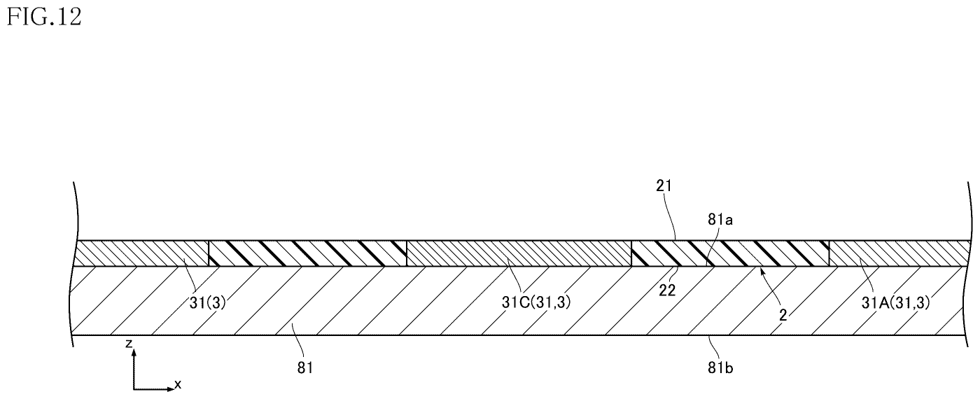

Next, as shown in FIG. 12, the insulating layer 2 is ground, and a plurality of terminal portions 31 are formed. In the grinding of the insulating layer 2, in the configuration shown in FIG. 11, grinding is performed from the insulating layer obverse surface 21 downward in the thickness direction z until the column bodies 82 are exposed from the insulating layer obverse surface 21. A grinding method is not particularly limited. Alternatively, the insulating layer 2 may be thinned by a non-grinding method. Thus, from the column bodies 82, the terminal portions 31 are formed. The formed terminal portions 31 include ground terminal portions 31A, corner terminal portions 31B, and a center terminal portion 31C. In the thickness direction z, the center terminal portion 31C is disposed so as to overlap with the electronic element.

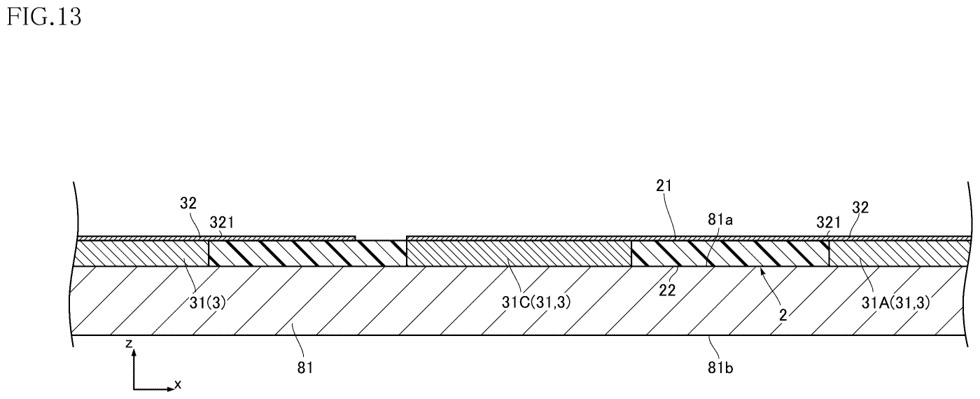

Next, as shown in FIG. 13, wiring portions 32 are formed. The wiring portions 32 are formed, for example, by the following steps. First, the seed layer 3201 is formed on the insulating layer obverse surface 21 and on the terminal portions 31. The seed layer 3201 is formed, for example, by a sputtering method. For example, as the seed layer, a Ti (titanium) layer and a Cu (copper) layer are laminated in this order. Next, a resist is patterned on the seed layer 3201, and the plating layer 3202 is formed by electrolytic plating. For example, the plating layer 3202 contains Cu (copper). Thereafter, the resist layer and an unnecessary part of the seed layer 3201 (a part of the seed layer 3201 exposed from the plating layer 3202) are removed. Through these steps, the wiring portions 32 are formed.

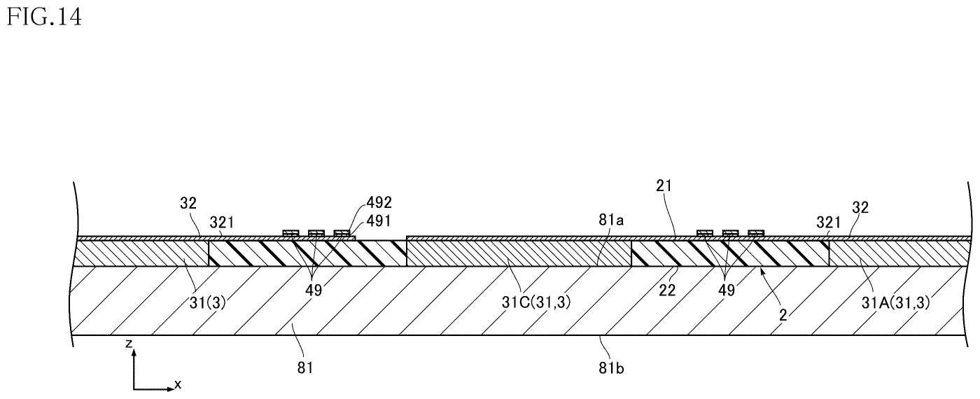

Next, as shown in FIG. 14, the barrier metals 491 and the solder layers 492 are sequentially formed. Each barrier metal layer 491 is made of a metal different from that of the wiring portion 32, e.g., nickel (Ni). In forming solder layer 492, for example, a solder paste serving as solder layer 492 is formed on a corresponding one of the barrier metals 491 by screen printing. Methods of forming the barrier metals 491 and the solder layers 492 are not particularly limited and may be, for example, electrolytic plating. By this electrolytic plating, a seed layer serving as a conductive path may be newly formed, or the seed layer 3201 formed in the step of forming the wiring portions 32 may be used without removal. The barrier metals 491 and the solder layers 492 are formed in regions where the electronic element 4 is to be bonded, respectively.

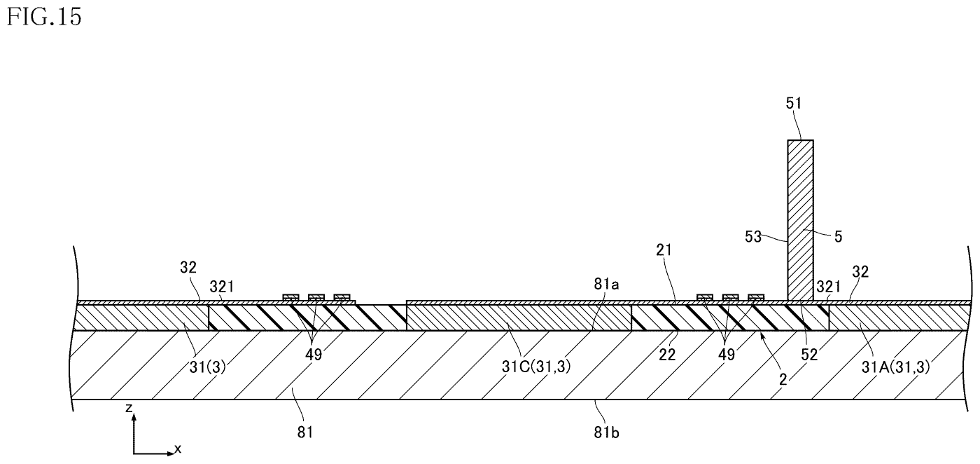

Next, as shown in FIG. 15, the columnar portions 5 are formed. Each columnar portion 5 contains a metal material such as Cu (copper). The columnar portions 5 are formed, for example, by electrolytic plating. In this electrolytic plating, a seed layer serving as a conduction path may be newly formed, or the seed layer 3201 formed in the step of forming the wiring portions 32 may be used without removal.

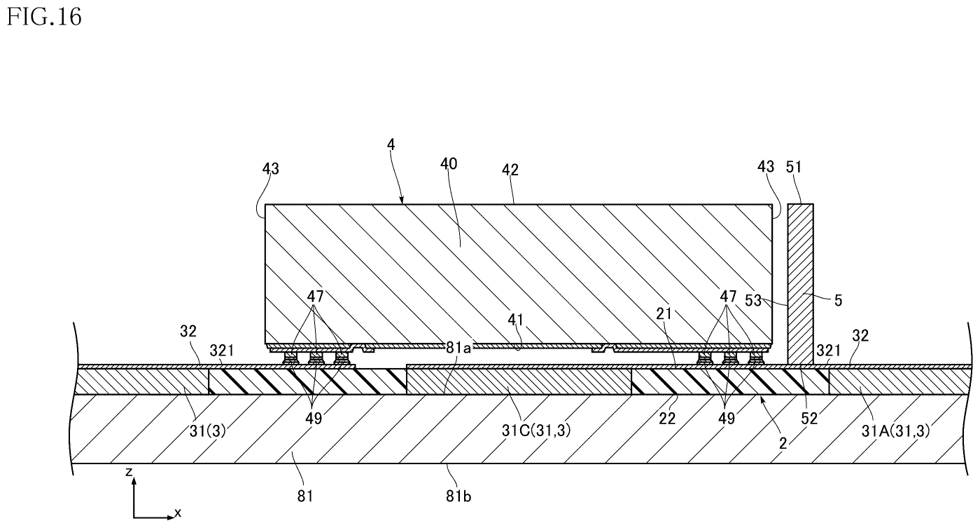

Next, as shown in FIG. 16, the electronic element 4 is placed and bonded. In the step of placing the electronic element 4 as shown in FIG. 15, the electrodes 47 of the electronic element 4 are aligned with the solder layers 492, respectively. Next, with the electronic element 4 placed, reflow is performed. By heat in this reflow, the solder layers 492 are melted. Next, the melted solder layers 492 are cooled. Thus, the solder layers 492 are solidified, and the electronic element 4 is bonded. As described above, the electronic element 4 is flip-chip mounted with the element obverse surface 41 facing the wiring portions 32.

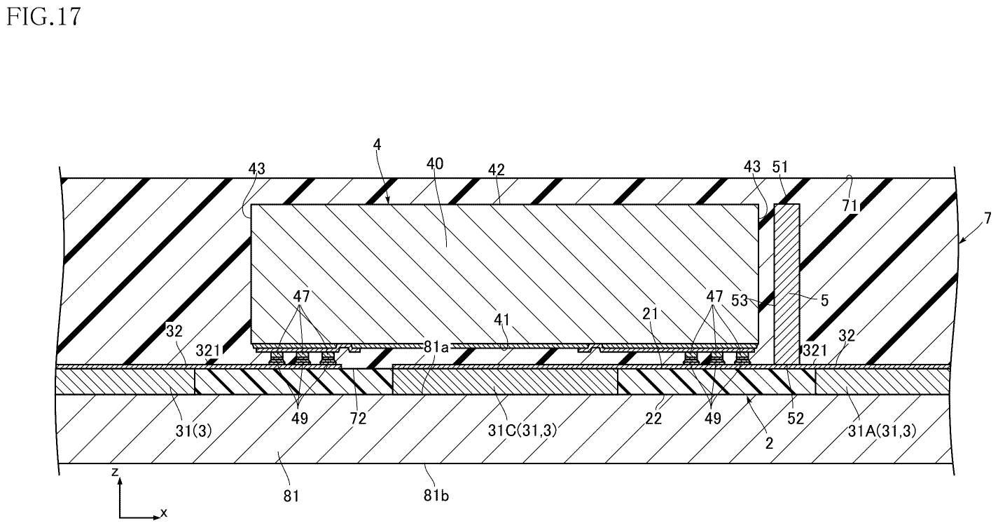

Next, as shown in FIG. 17, the sealing resin 7 is formed. The sealing resin 7 is formed above the insulating layer 2 so as to cover the electronic element 4, the wiring portion 32, and the columnar portion 5. The sealing resin 7 is formed, for example, by molding. The sealing resin 7 is, for example, a synthetic resin mainly composed of a black epoxy resin. As the sealing resin 7, an insulating resin material other than the synthetic resin may be used. The sealing resin 7 has the resin obverse surface 71 facing upward in the thickness direction z and the resin reverse surface 72 facing downward in the thickness direction z.

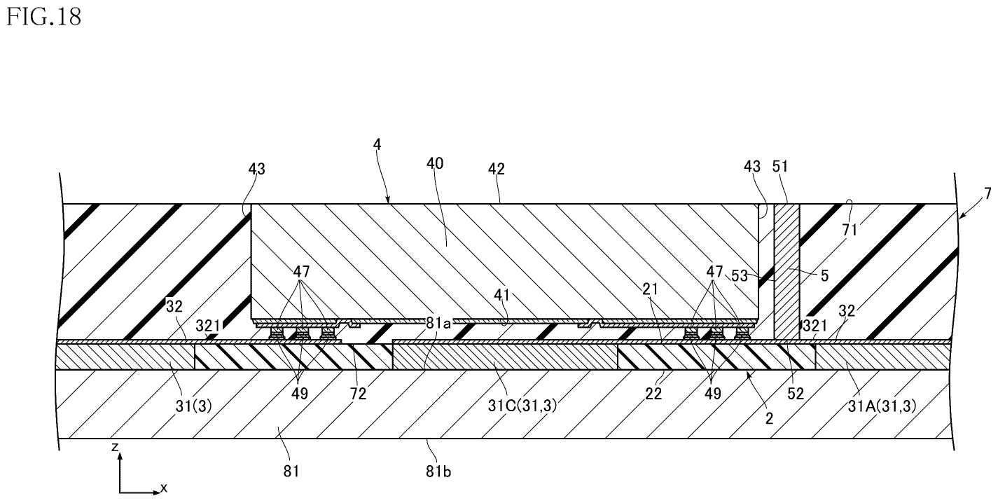

Next, as shown in FIG. 18, the sealing resin 7 may be ground from the resin obverse surface 71 downward in the thickness direction z until the element reverse surface 42 and at least one of the columnar portion obverse surfaces 51 are exposed. A grinding method is not particularly limited. Alternatively, the sealing resin 7 may be thinned by a non-grinding method such as a chemical technique.

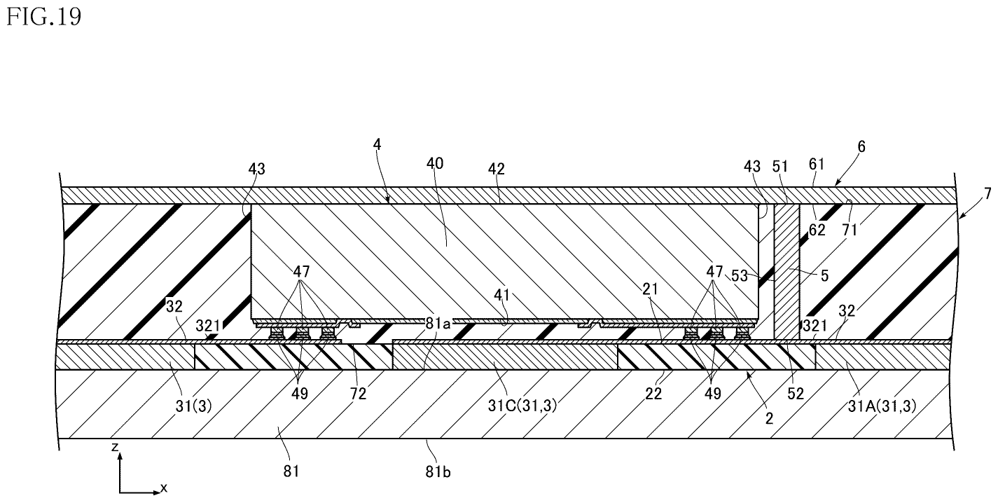

Next, as shown in FIG. 19, the metal layer 6 is formed. At this time, the metal layer 6 may be formed so as to connect to both the element reverse surface 42 and at least one of the columnar portion obverse surfaces 51. The metal layer 6 contains a metal material such as Cu (copper). The metal layer 6 is formed, for example, by electrolytic plating. The forming of the metal layer 6 may not be necessary.

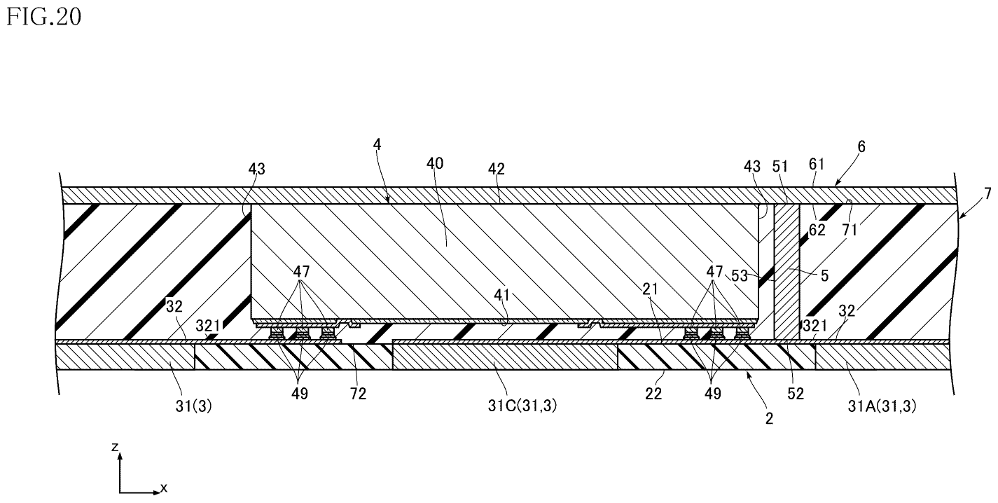

Next, as shown in FIG. 20, the support substrate 81 is removed. In removing the support substrate 81, for example, in the configuration shown in FIG. 20, the support substrate 81 is ground from a side of the support substrate reverse surface 81b. By continuing the grinding even after removing the support substrate 81, the insulating layer 2 and the terminal portions 31 may be thinned.

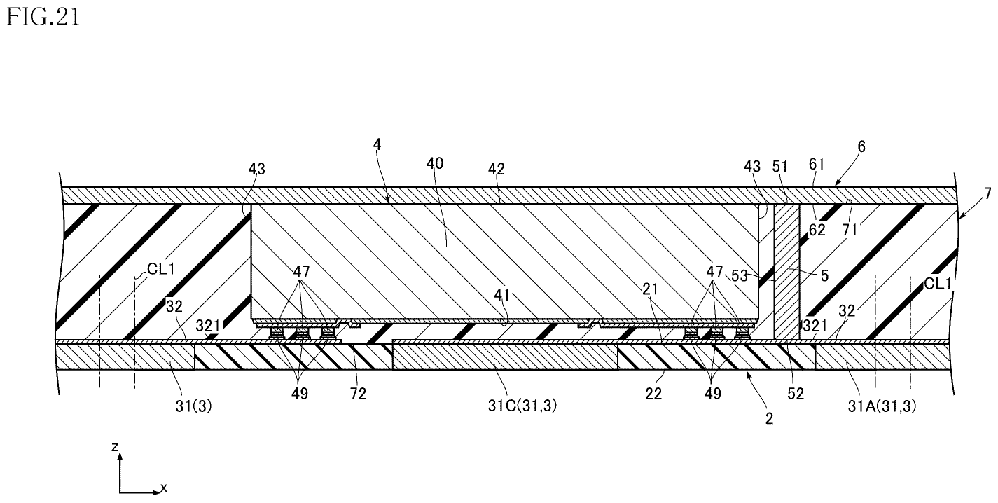

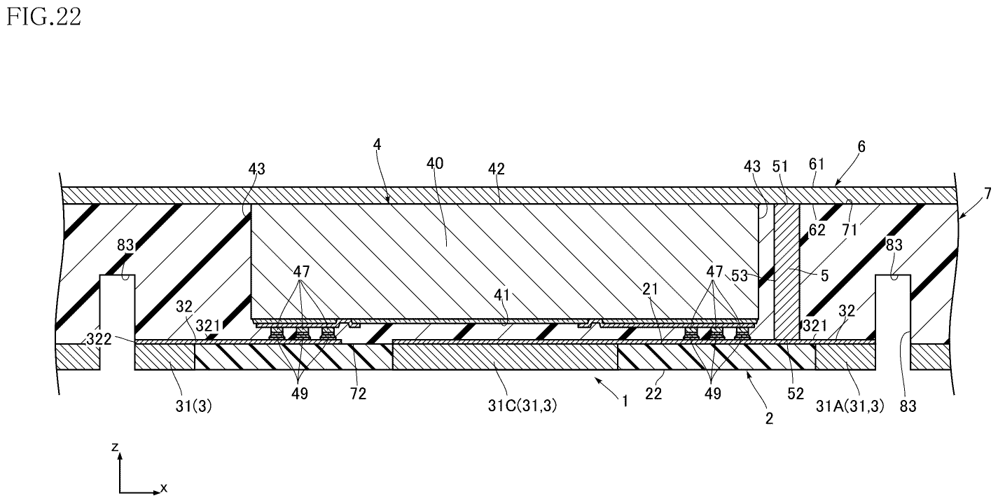

Next, as shown in FIG. 21, the sealing resin 7 and the insulating layer 2 are cut along a dicing line CL1 from a side of the insulating layer reverse surface 22 to a part of the sealing resin 7. Cutting the sealing resin 7 and the insulating layer 2 is performed, for example, by machining using a dicing blade. Thus, as shown in FIG. 22, a groove portion 83 is formed in a part of the sealing resin 7 and in the insulating layer 2.

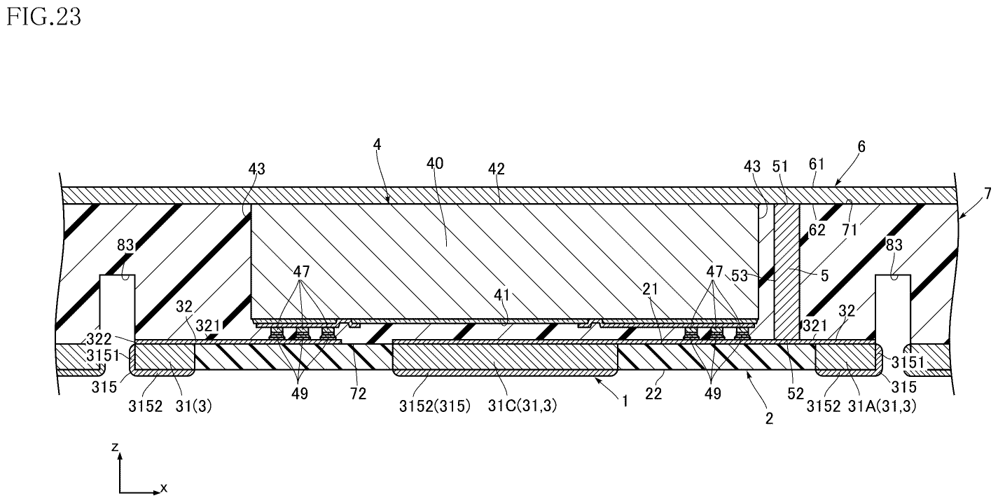

Next, as shown in FIG. 23, the conductor films 315 are formed. Each conductor film 315 has the lower conductor film 3152 that is in contact with the corresponding terminal portion reverse surface 312. Each conductor film 315 may have the side conductor film 3151 that is in contact with the corresponding terminal portion side surface 313.

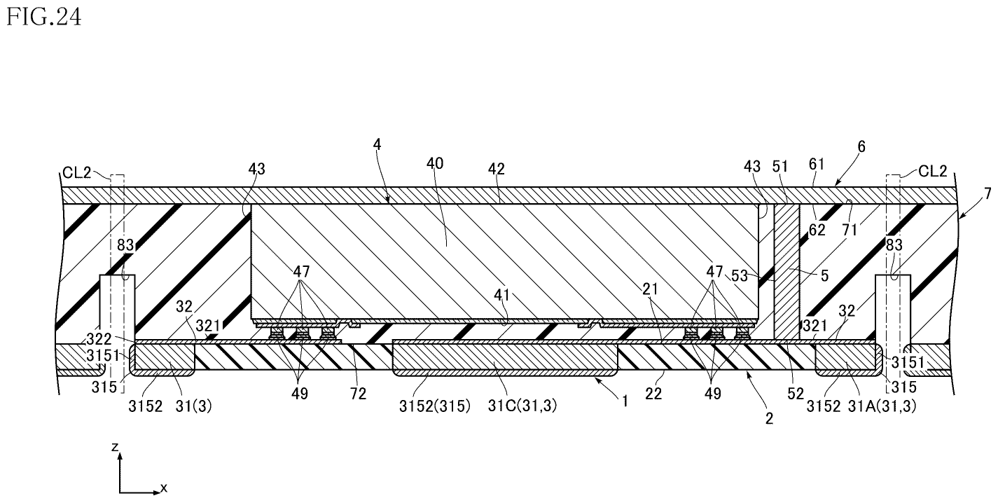

Next, as shown in FIG. 24, the sealing resin 7 and the metal layer 6 are cut along a dicing line CL2. Cutting the sealing resin 7 and the metal layer 6 is performed, for example, by machining using a dicing blade. Thus, the sealing resin 7 and the metal layer 6 are divided at the dicing line CL2.

Through the above steps, the electronic device A10 shown in FIGS. 1 to 9 is manufactured. The method of manufacturing the electronic device A10 is not limited to the above-described example.

Operative effects of the electronic device A10 will be described.

The electronic device A10 includes at least one of the columnar portions 5 projecting upward in the thickness direction z from the conductive portion 3 within the sealing resin 7. Accordingly, heat transferred from the electronic element 4 to the sealing resin 7 readily transfers to the conductive portion 3 via at least one of the columnar portions 5. Thus, heat generated from the electronic element 4 can be released to the outside more quickly. Further, at least one of the columnar portion obverse surfaces 51 is formed so as to penetrate the resin obverse surface 71 in the thickness direction z. Therefore, heat generated from the electronic element 4 can be released to the outside more quickly.

In the electronic device A10, the metal layer reverse surface 62 of the metal layer 6 is in contact with at least one of the columnar portion obverse surfaces 51 and with the element reverse surface 42 in the thickness direction z. Accordingly, heat generated from the electronic element 4 may be dissipated, via the metal layer 6, at least one of the columnar portions 5, and at least one of the wiring portions 32, to a mounting substrate (not shown) on which the electronic device A10 is mounted. Therefore, with such a configuration, the electronic device A10 has an advantage to enhance heat dissipation.

At least one of the columnar portions 5 is electrically connected to at least one of the ground terminal portions 31A. A ground line to which the ground terminal portions 31A is connected generally has a large area and readily conducts heat. Accordingly, heat dissipation from the electronic element 4 can be promoted. In the present embodiment, at least one of the columnar portions 5 is electrically connected to the center terminal portion 31C. The center terminal portion 31C has the largest area among the terminal portions 31. Therefore, such a configuration is advantageous for promoting heat dissipation from the electronic element 4.

The electronic device A10 includes the electronic element 4, the insulating layer 2, and at least one of the columnar portions 5. The insulating layer 2 has an insulating layer obverse surface 21 that supports the electronic element 4. At least one of the columnar portions 5 is disposed on the insulating layer obverse surface 21 (in a direction in which the insulating layer obverse surface 21 faces with respect to the insulating layer 2). With such a configuration, at least one of the columnar portions 5 functions as an electromagnetic shield. This can prevent the electronic element 4 from being affected by external electromagnetic noise. Accordingly, such a configuration can improve operational reliability of the electronic device A10.

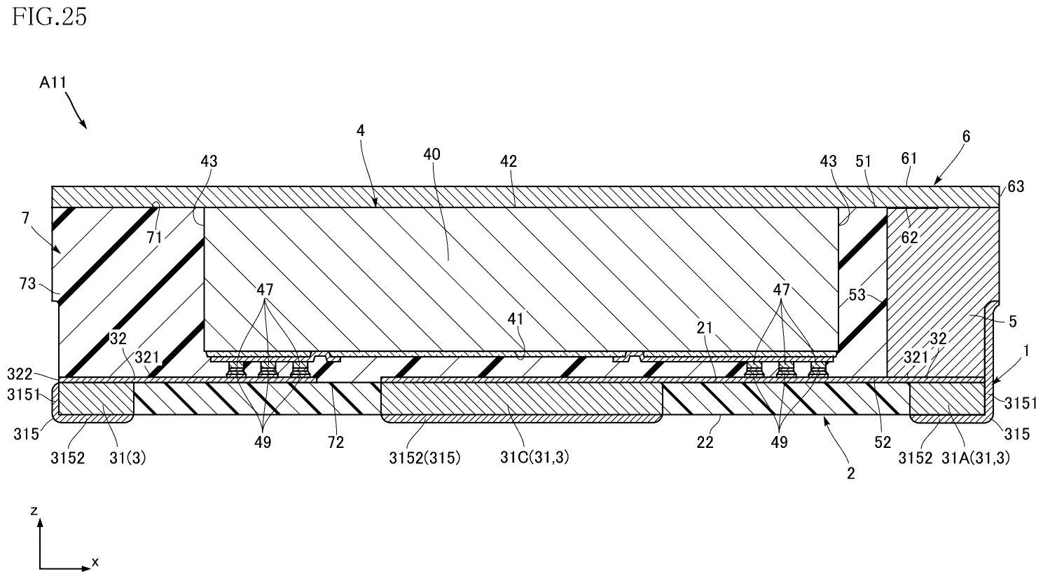

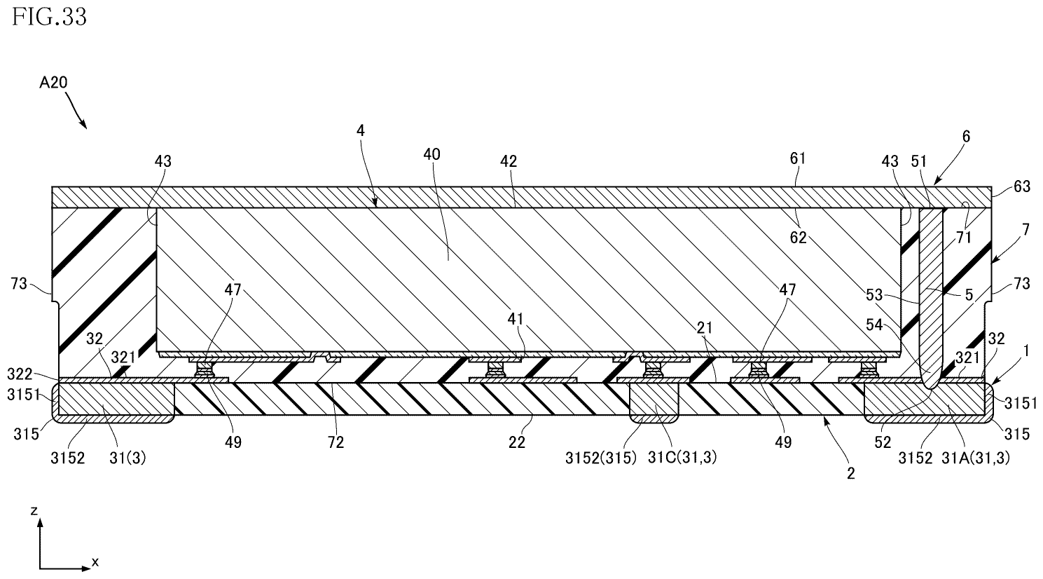

FIGS. 25 to 44 show variations and other embodiments of the present disclosure. In these drawings, elements identical or similar to those of the embodiment described above are marked with the same numerals, and redundant descriptions are omitted. Various parts of the respective embodiments and variations can be appropriately combined with one another insofar as no technical inconsistencies arise.

FIG. 25 shows a first variation of the electronic device A10. An electronic device A11 of the present variation differs from the electronic device A10 in the configuration of at least one of the columnar portions 5.

In the electronic device A11, at least one of the columnar portions 5 is exposed from the sealing resin 7 in the x direction. Such a columnar portion 5 can be formed by forming a columnar portion 5 having a larger size in the x direction than the columnar portion 5 shown in FIG. 15. For example, as viewed in the thickness direction z, at least one of the columnar portions 5 is formed so as to overlap with a corresponding one of the terminal portions 31 (the ground terminal portion 31A in the drawing). Then, in the steps shown in FIGS. 21 and 24, cutting is performed so as to remove a part of at least one of the columnar portions 5. In the electronic device A11, at least one of the side conductor films 3151 of the conductor film 315 may be formed on a part of the columnar portion 5.

Also with the present variation, heat generated from the electronic element 4 can be released to the outside more quickly. Further, as understood from the present variation, the columnar portion 5 may be exposed from the sealing resin 7 in the x direction or in the y direction.

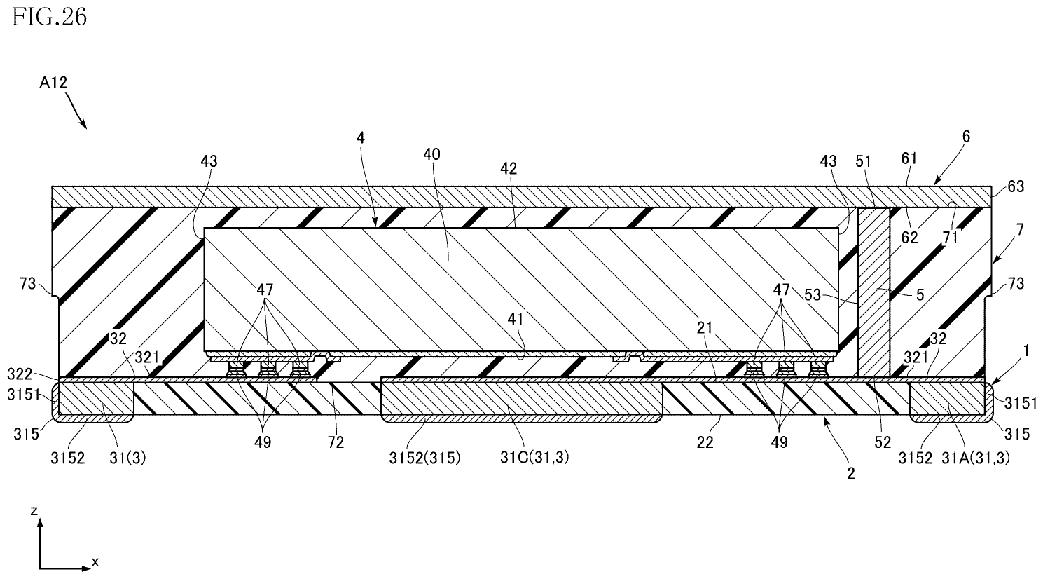

FIG. 26 shows a second variation of the electronic device A10. An electronic device A12 of the present variation differs from the examples described above in the relationship between the electronic element 4 and the metal layer 6.

In the electronic device A12, a part of the sealing resin 7 is interposed between the element reverse surface 42 of the electronic element 4 and the metal layer reverse surface 62 of the metal layer 6.

Also with the present variation, heat generated from the electronic element 4 can be released to the outside more quickly. Further, as understood from the present variation, the electronic device of the present disclosure is not limited to a configuration in which the electronic element 4 and the metal layer 6 are in contact with each other.

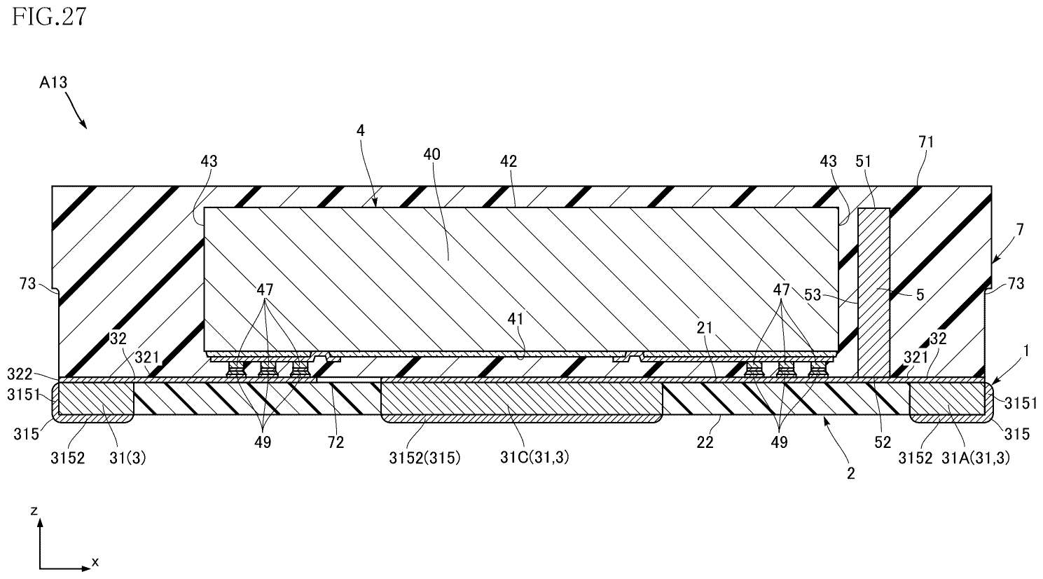

FIG. 27 shows a third variation of the electronic device A10. An electronic device A13 of the present variation does not include the metal layer 6.

In the electronic device A13, the resin obverse surface 71 of the sealing resin 7 is exposed upward in the z direction. In the illustrated example, the element reverse surface 42 of the electronic element 4 and the columnar portion obverse surfaces 51 of the columnar portions 5 are covered with the sealing resin 7, but the present disclosure is not limited thereto. At least one of the element reverse surface 42 and the columnar portion obverse surface 51 may be exposed from the resin obverse surface 71 of the sealing resin 7.

Also with the present variation, heat generated from the electronic element 4 can be released to the outside more quickly. Further, as understood from the present variation, the electronic device of the present disclosure may have a configuration without the metal layer 6.

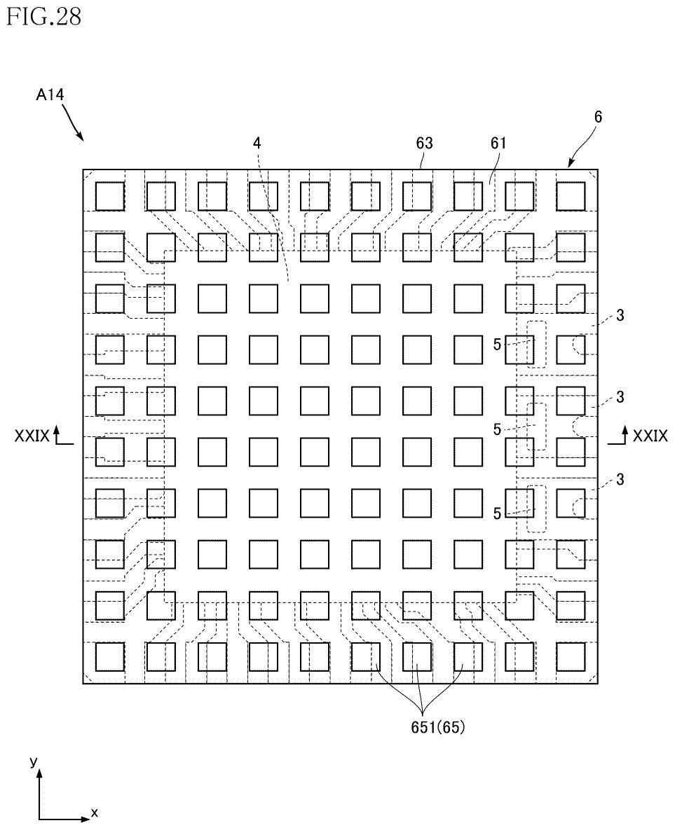

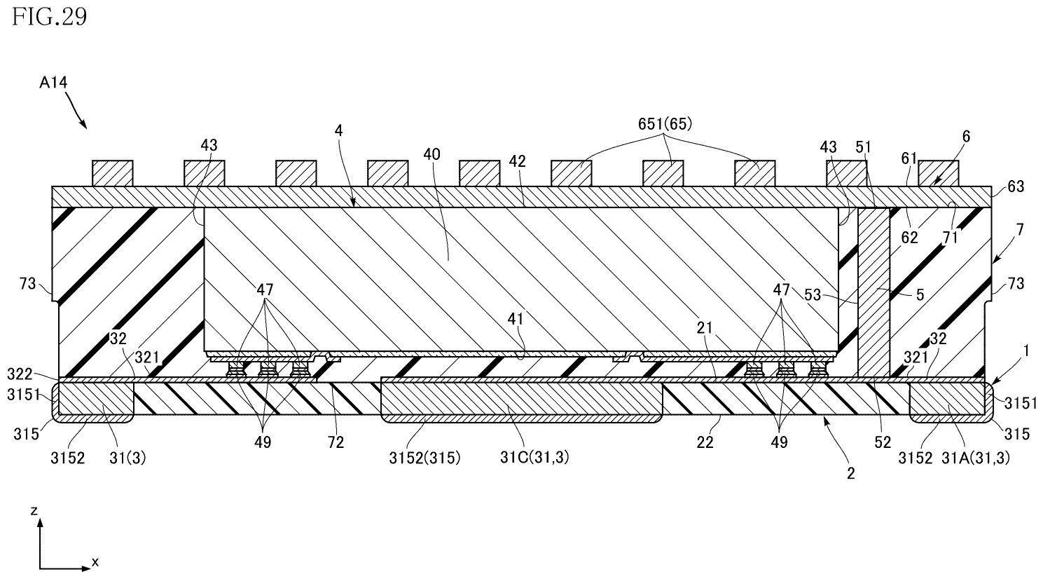

FIGS. 28 and 29 show a fourth variation of the electronic device A10. An electronic device A14 of the present variation differs from the examples described above in the configuration of the metal layer 6.

In the electronic device A14, the metal layer 6 has an uneven portion 65. The uneven portion 65 is formed on the upper side of the metal layer 6 in the thickness direction z. In the illustrated example, the uneven portion 65 includes a plurality of protrusions 651. Each of the protrusions 651 projects upward in the thickness direction z from the metal layer obverse surface 61. A size of the uneven portion 65 in the thickness direction z is not particularly limited and is, for example, in a range from 3 μm to 100 μm.

Shapes and sizes of the protrusions 651 are not particularly limited. In the present example, each of the protrusions 651 is rectangular as viewed in the thickness direction z; however, circular, elliptical, polygonal, or other shapes may be adopted. An arrangement of the protrusions 651 is not particularly limited, and in the present example, is a matrix pattern along the first direction x and the second direction y.

A method of forming the uneven portion 65 (the protrusions 651) is not particularly limited. For example, after the step shown in FIG. 19, the uneven portion 65 (the protrusions 651) may further be formed by electrolytic plating. Alternatively, the metal layer 6 may be formed thicker in the thickness direction z than shown in FIG. 19 and then etched to form the uneven portion 65 (including a plurality of protrusions 651).

Also with the present variation, heat generated from the electronic element 4 can be released to the outside more quickly. In the present variation, the metal layer 6 has the uneven portion 65. This enlarges the surface area of the metal layer 6 on the upper side in the thickness direction z. Therefore, such a configuration is suitable for enhancing heat dissipation of the electronic device A14.

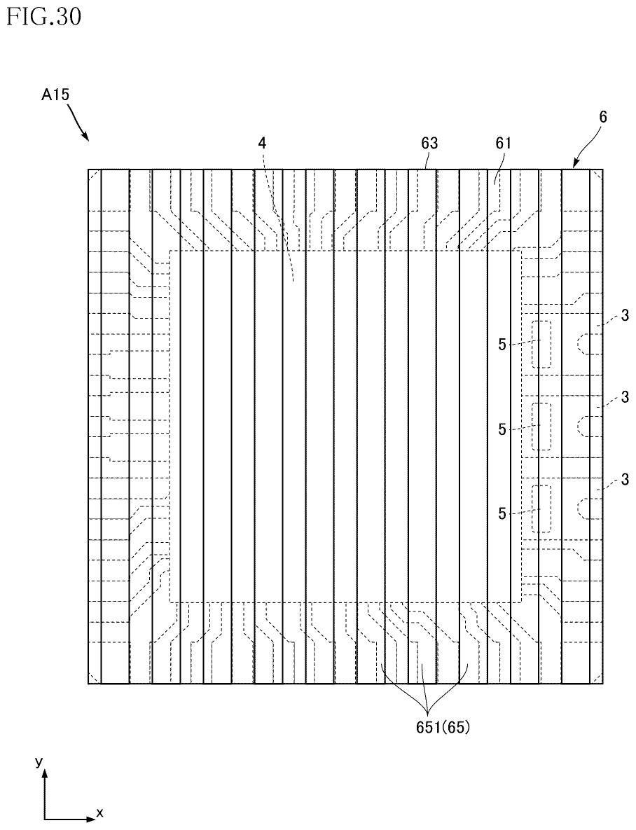

FIG. 30 shows a fifth variation of the electronic device A10. An electronic device A15 of the present variation differs from the electronic device A14 in the configuration of the protrusions 651.

In the electronic device A15, the protrusions 651 each extend along the second direction y and reach both ends of the metal layer 6 in the second direction y. The protrusions 651 are parallel to each other and are spaced apart from each other in the first direction x.

Also with the present variation, heat generated from the electronic element 4 can be released to the outside more quickly. Further, as understood from the present variation, a specific configuration of the uneven portion 65 (the protrusions 651) is not particularly limited.

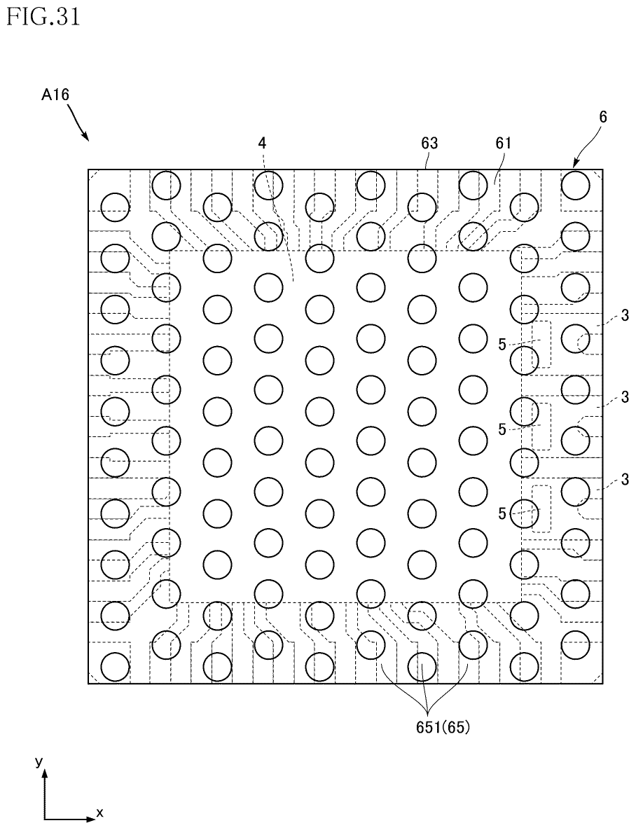

FIG. 31 shows a sixth variation of the electronic device A10. An electronic device A16 of the present variation differs from the examples described above in the configuration of the protrusions 651.

In the electronic device A16, the protrusions 651 are each circular as viewed in the thickness direction z. The protrusions 651 are arranged in a matrix pattern, and are arranged such that positions of protrusions 651 that are adjacent in the first direction x are offset from each other in the second direction y.

Also with the present variation, heat generated from the electronic element 4 can be released to the outside more quickly. Further, as understood from the present variation, a specific configuration of the uneven portion 65 (the protrusions 651) is not particularly limited.

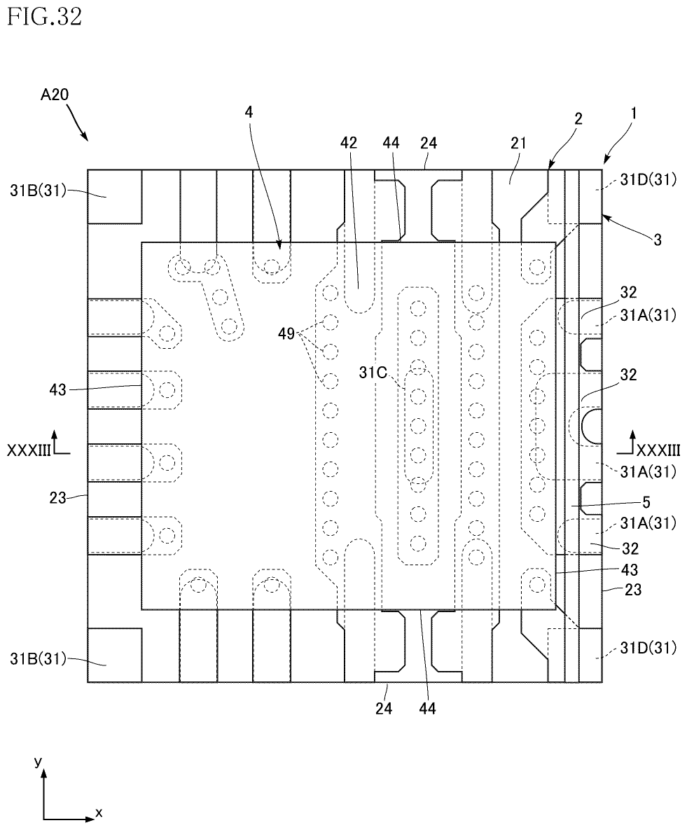

FIGS. 32 to 34 show an electronic device A20 according to a second embodiment. In the electronic device A20, a configuration of the columnar portion 5 differs from that of the embodiment described above.

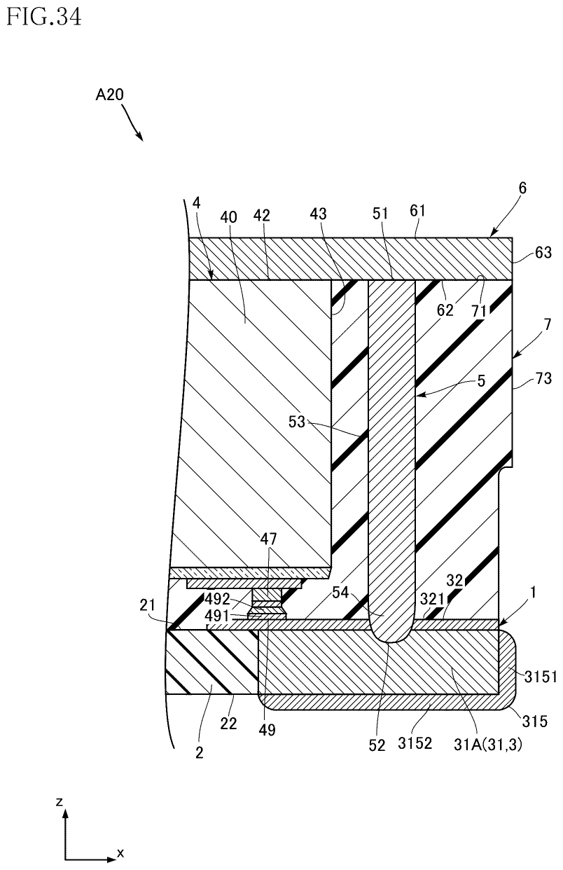

The columnar portion 5 of the present embodiment includes a tapered portion 54. The tapered portion 54 is connected to the wiring portions 32. The tapered portion 54 is a lower end of the columnar portion 5 in the thickness direction z. As shown in FIG. 34, the tapered portion 54 has a cross section orthogonal to the thickness direction z that decreases in size from an upper side (first side) toward a lower side (second side). In the illustrated example, a size of the tapered portion 54 in the first direction x decreases from the upper side (first side) toward the lower side (second side) in the thickness direction z. There is no particular limitation on the shape of the portion of the columnar portion 5 located above the tapered portion 54 in the thickness direction z. In the illustrated example, a shape and a size of a cross section orthogonal to the thickness direction z of the relevant portion are constant.

The tapered portion 54 is connected to at least one of the wiring portions 32. In the illustrated example, the tapered portion 54 is connected to at least one of the wiring portions 32 that is electrically connected to the relevant ground terminal portion 31A. The conductive portion 3 of the electronic device A20 further includes two ground terminal portions 31D. The two ground terminal portions 31D are disposed on both sides in the second direction y with a plurality of the ground terminal portions 31A interposed therebetween. The tapered portion 54 is connected to at least one of the wiring portions 32 that is electrically connected to the two ground terminal portions 31D.

As shown in FIG. 34, in the illustrated example, the tapered portion 54 penetrates at least one of the wiring portions 32 and reaches the relevant terminal portion 31. There is no particular limitation on a specific connection configuration between the tapered portion 54 and the wiring portion 32, and the tapered portion 54 may extend only to the wiring portion 32, or may extend through the wiring portion 32 to reach the terminal portion 31.

As shown in FIG. 32, the columnar portion 5 extends across the electronic device A20 in the second direction y and reaches both ends in the second direction y. In the illustrated example, a shape and a size of a cross section of the columnar portion 5 orthogonal to the second direction y are substantially constant.

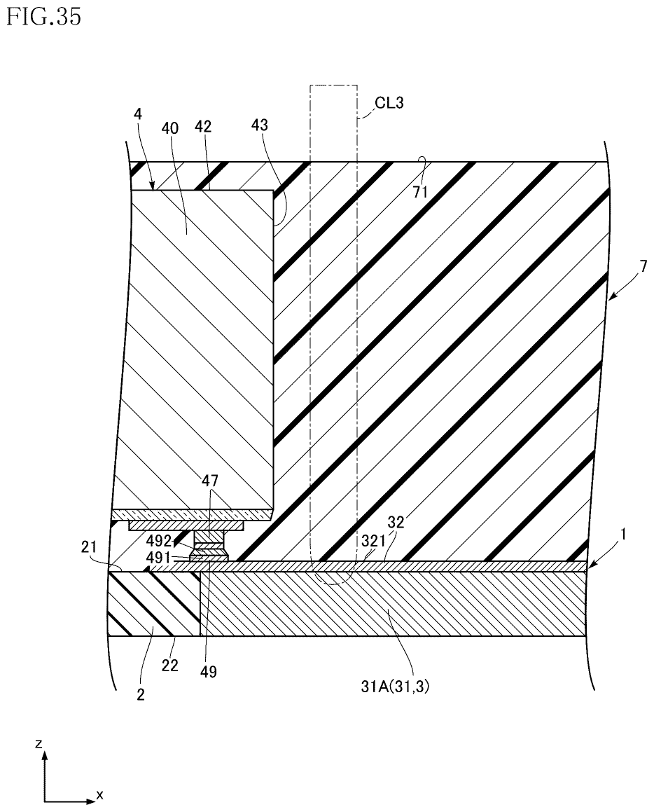

Next, an example of a method of manufacturing the electronic device A20 will be described below with reference to FIGS. 35 to 40.

First, the steps described with reference to FIGS. 10 to 17 are performed, except that the forming of the columnar portion 5 shown in FIG. 15 is not performed.

Next, as shown in FIG. 35, the sealing resin 7 is cut along a dicing line CL3. This cutting is performed, for example, by machining using a dicing blade. In the illustrated example, a tapered portion is provided at a peripheral portion of the dicing blade. A lower end in the thickness direction z of the dicing line CL3 corresponds to a shape of this tapered portion. In the illustrated example, the dicing line CL3 penetrates at least one of the wiring portions 32 and reaches the relevant terminal portion 31. The dicing line CL3 need only reach the wiring portion 32 and need not reach the terminal portion 31. Cutting along the dicing line CL3 is performed over the entire extent in the second direction y.

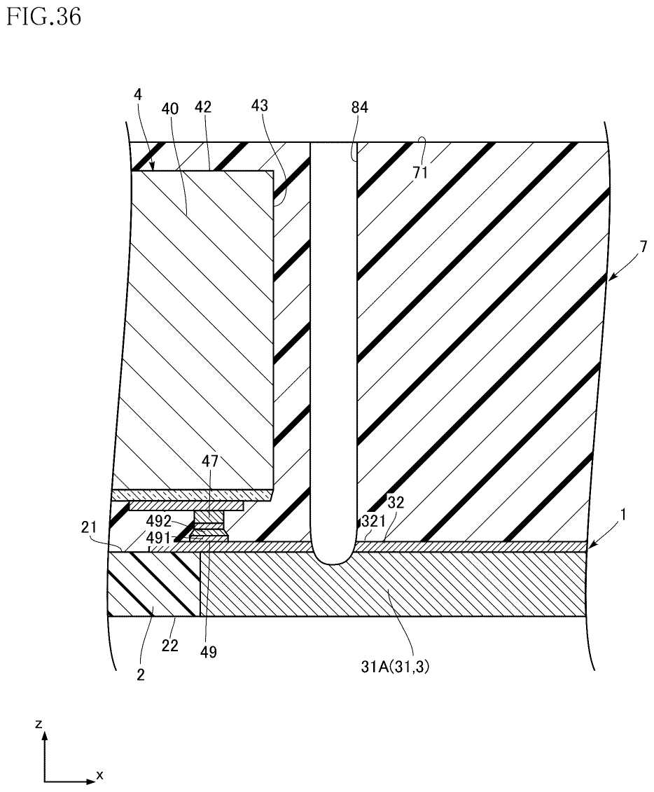

Cutting along the dicing line CL3 forms a groove portion 84 shown in FIG. 36. The groove portion 84 opens at the resin obverse surface 71 and is recessed downward in the thickness direction z from the resin obverse surface 71. The groove portion 84 reaches at least one of the wiring portions 32. In the illustrated example, the groove portion 84 reaches the relevant terminal portion 31.

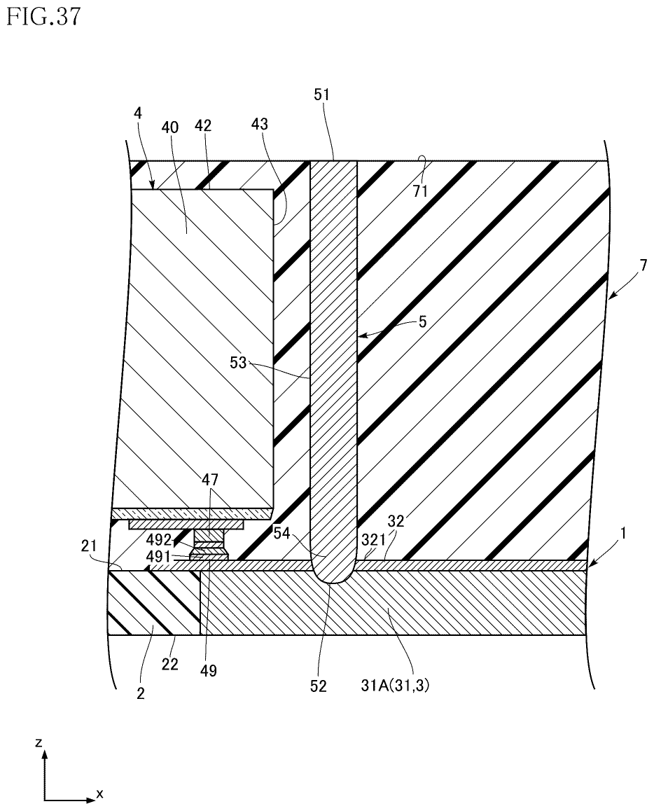

Next, by filling the groove portion 84 with a conductor, the columnar portion 5 shown in FIG. 37 is formed. A technique for filling the groove portion 84 with the conductor is not particularly limited. For example, Cu (copper), which is one example of a conductor, may be filled into the groove portion 84 by electrolytic plating after forming a metal layer serving as a seed layer on an inner surface of the groove portion 84 by sputtering or the like. Since the columnar portion 5 is formed corresponding to a shape of the groove portion 84, in the illustrated example, the tapered portion 54 is formed in the columnar portion 5.

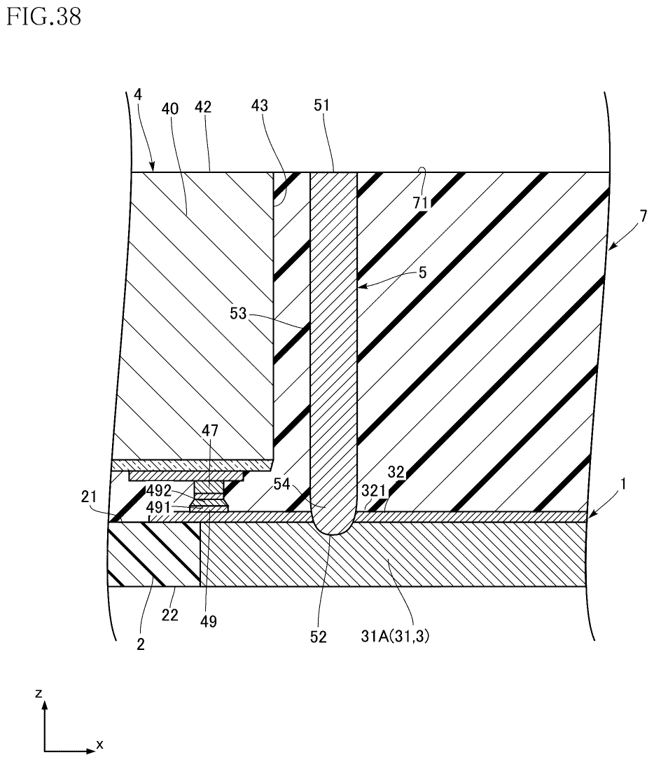

Next, as shown in FIG. 38, the sealing resin 7 and the columnar portion 5 are cut from an upper side in the thickness direction z. Thereby, the element reverse surface 42 is exposed from the resin obverse surface 71.

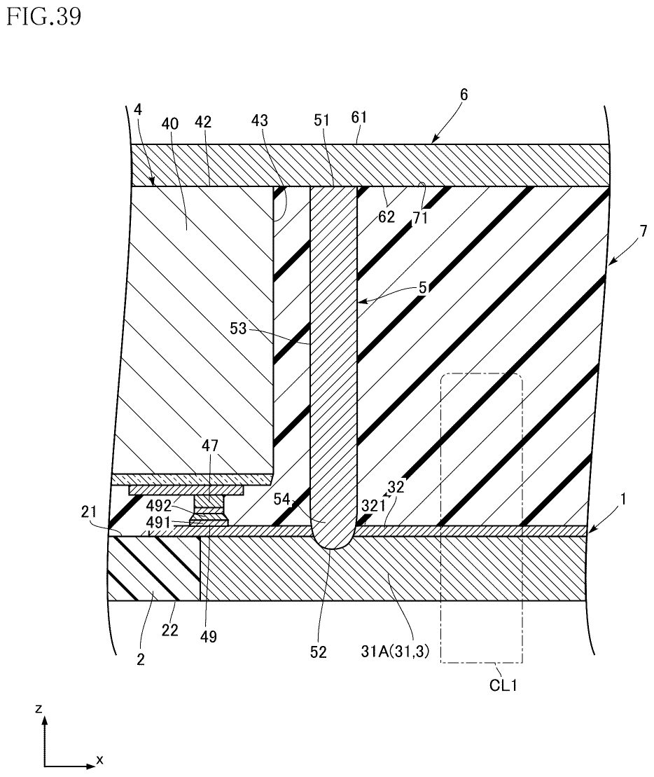

Next, as shown in FIG. 39, the metal layer 6 is formed. Note that, in FIGS. 35 to 39, the support substrate 81 shown in FIGS. 10 to 19 is not illustrated, but the manufacturing method using the support substrate 81 as in the steps of FIGS. 10 to 19 may be adopted.

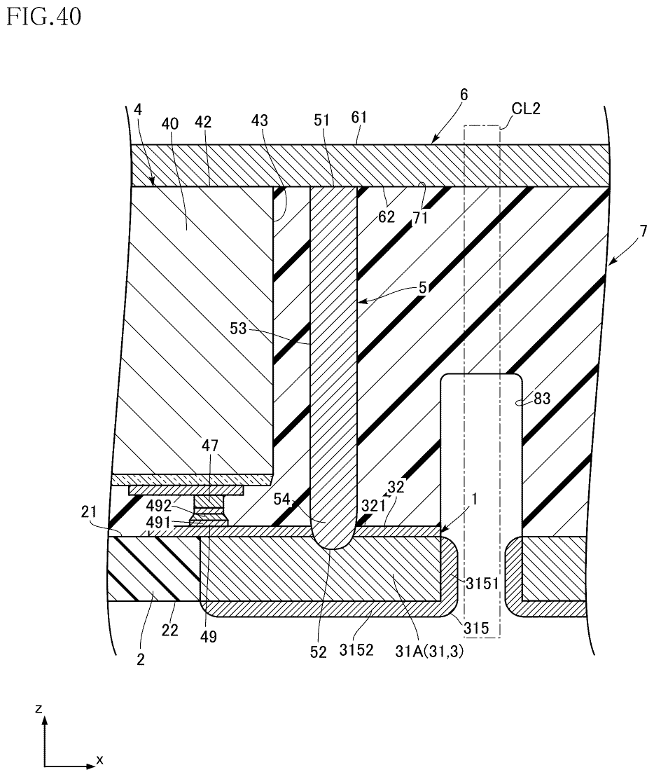

Next, along the dicing line CL1 shown in FIG. 39, a part of the substrate 1 and a part of the sealing resin 7 are cut. Next, as shown in FIG. 40, the conductor films 315 are formed, and cutting along a dicing line CL2 is performed, for example. Through the above steps, the electronic device A20 is obtained.

Also with the present embodiment, heat generated from the electronic element 4 can be released to the outside more quickly. Further, the groove portion 84 as shown in FIG. 36 is formed by the cutting shown in FIG. 35, and the columnar portion 5 is formed by filling the groove portion 84 with the conductor. With such a technique, it is possible to form the columnar portion 5 having a comparatively large size at a desired position, which is advantageous for enhancing heat dissipation.

The tapered portion 54 is connected to the wiring portion 32, so that heat can be transferred more reliably between the columnar portion 5 and the conductive portion 3. Further, a configuration in which the tapered portion 54 penetrates at least one of the wiring portions 32 and reaches the relevant terminal portion 31 is preferable for promoting heat transfer.

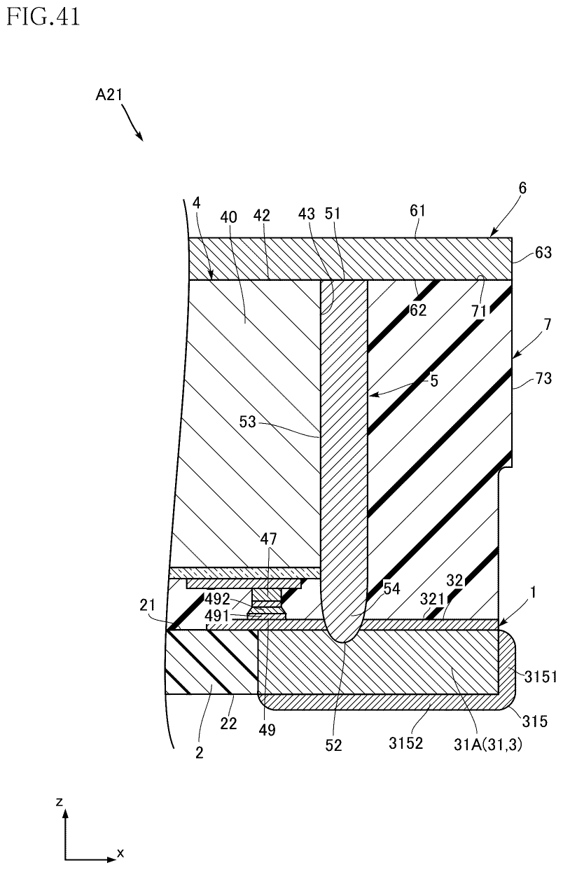

FIG. 41 shows a first variation of the electronic device A20. An electronic device A21 of the present variation differs from the examples described above in configurations of the electronic element 4 and the columnar portion 5.

In the electronic device A21, the element side surface 43 of the electronic element 4 and the columnar portion side surface 53 of the columnar portion 5 are in contact with each other. No sealing resin 7 is interposed between the element side surface 43 and the columnar portion side surface 53. The element reverse surface 42 and the columnar portion obverse surface 51 are flush with each other.

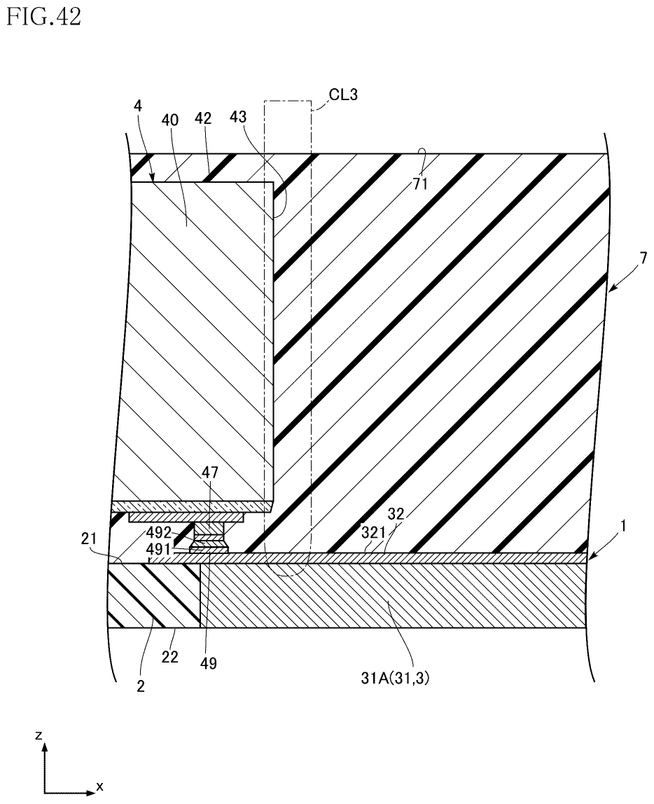

FIGS. 42 to 44 show an example of a method of manufacturing the electronic device A21. As shown in FIG. 42, cutting along the dicing line CL3 is performed. In the present embodiment, the dicing line CL3 overlaps with the sealing resin 7 and the electronic element 4.

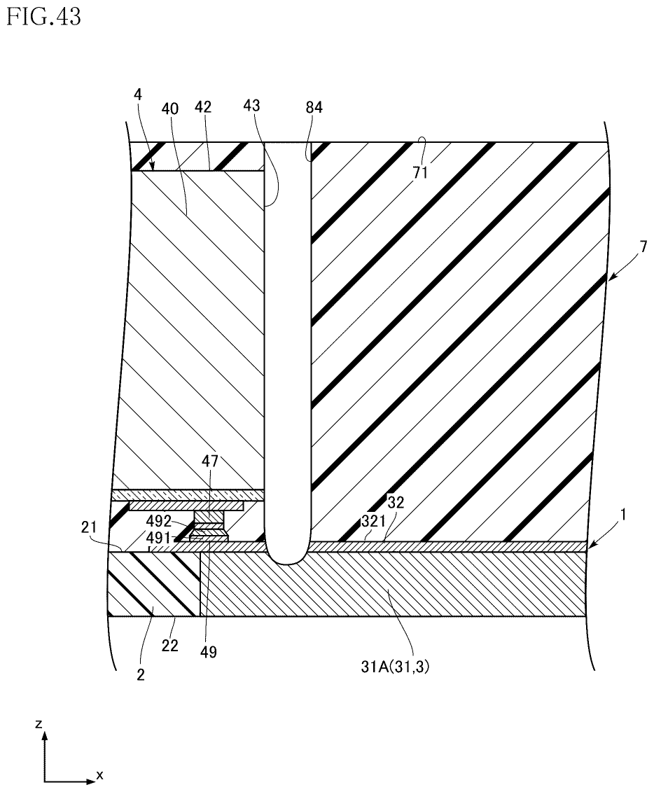

Cutting along the dicing line CL3 forms the groove portion 84 shown in FIG. 43 and cuts a part of the electronic element 4. In this cutting, for example, a portion without an electrical functional portion of the electronic element 4 is cut. As a result, the element side surface 43 is exposed at the groove portion 84 of the electronic element 4.

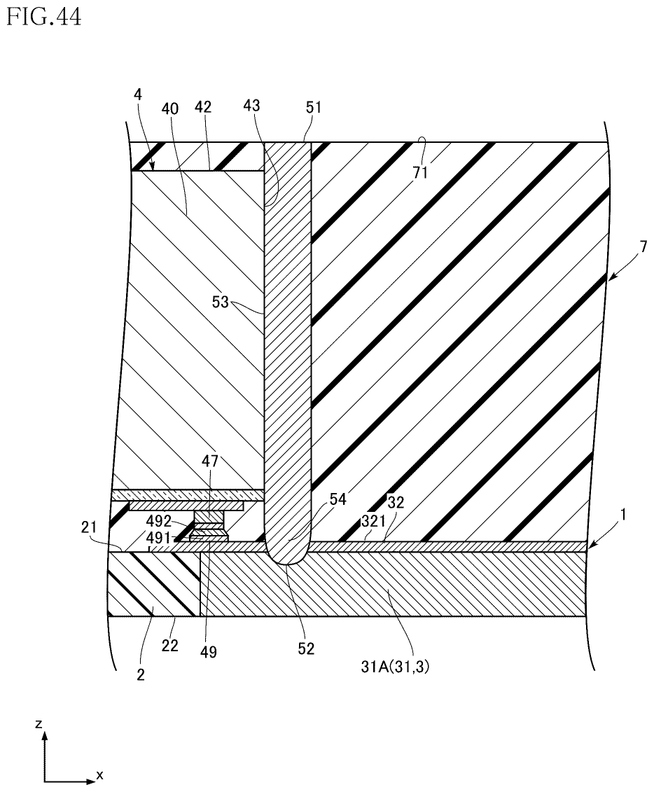

Next, as shown in FIG. 44, by filling the groove portion 84 with a conductor, the columnar portion 5 is formed. Thereafter, for example, through the steps shown in FIGS. 38 to 40, the electronic device A21 is obtained.

Also with the present embodiment, heat generated from the electronic element 4 can be released to the outside more quickly. Further, since the electronic element 4 and the columnar portion 5 are in contact with each other, heat from the electronic element 4 is efficiently transferred to the columnar portion 5. This is advantageous for enhancing heat dissipation of the electronic device A21.

The electronic device according to the present disclosure is not limited to the above-described embodiments. The specific configuration of each part of the electronic device according to the present disclosure may be freely changed in design.

The present disclosure includes the configurations described in the following clauses.

Clause 1.

An electronic device comprising:
a substrate including:
   an insulating layer having an insulating layer obverse surface facing a first side in a thickness direction and an insulating layer reverse surface facing a second side opposite to the first side in the thickness direction, and
   a conductive portion exposed from the insulating layer obverse surface and from the insulating layer reverse surface;
an electronic element including:
   an element body having an element obverse surface facing the insulating layer obverse surface in the thickness direction, and
   a plurality of electrodes disposed on the element obverse surface, the plurality of electrodes being electrically bonded to the conductive portion;
a columnar portion projecting from the conductive portion toward the first side in the thickness direction and having electrical conductivity; and
a sealing resin covering the insulating layer obverse surface, the electronic element, and the columnar portion.

Clause 2.

The electronic device according to clause 1, wherein the element body has an element reverse surface facing the first side in the thickness direction, and,
the columnar portion extends beyond the element reverse surface toward the first side in the thickness direction.

Clause 3.

The electronic device according to clause 1 or 2, wherein the columnar portion has a columnar portion side surface extending in the thickness direction,
the element body has an element side surface extending in the thickness direction, and
the columnar portion side surface and the element side surface are in contact with each other at least in part.

Clause 4.

The electronic device according to any one of clauses 1 to 3, wherein the element body has an element reverse surface facing the first side in the thickness direction, and
the electronic element includes a metal layer disposed on the element reverse surface.

Clause 5.

The electronic device according to clause 4, wherein the metal layer is connected to the columnar portion.

Clause 6.

The electronic device according to clause 4 or 5, further comprising an insulating film laminated toward the first side in the thickness direction with respect to the metal layer. Clause 7.

The electronic device according to clause 1, wherein the conductive portion includes:
a terminal portion having a terminal reverse surface exposed from the insulating layer reverse surface, and
a wiring portion exposed from the insulating layer obverse surface and connecting the terminal portion and at least one of the plurality of electrodes.

Clause 8.

The electronic device according to clause 7, wherein at least a part of the electronic element overlaps with the terminal portion, as viewed in the thickness direction.

Clause 9.

The electronic device according to clause 7, wherein a metal film is provided on at least a part of the terminal portion.

Clause 10.

The electronic device according to any one of clauses 7 to 9, wherein the columnar portion includes a tapered portion connected to the wiring portion, and
the tapered portion has a cross-section orthogonal to the thickness direction decreasing in size from the first side toward the second side in the thickness direction.

Clause 11.

The electronic device according to clause 4 or 5, wherein the metal layer has an uneven portion on the first side in the thickness direction.

Clause 12.

The electronic device according to clause 11, wherein the uneven portion has a plurality of protrusions arranged in a first direction orthogonal to the thickness direction, as viewed in the thickness direction.

Clause 13.

The electronic device according to clause 11, wherein the plurality of protrusions are arranged in a matrix pattern, as viewed in the thickness direction.

Clause 14.

The electronic device according to any one of clauses 11 to 13, wherein the uneven portion has a thickness in a range of 3 μm to 100 μm.

Clause 15.

The electronic device according to clause 7, wherein the conductive portion includes a plurality of the terminal portions, the plurality of the terminal portions including a ground terminal portion for ground connection, and the columnar portion is electrically connected to the ground terminal portion.

Clause 16.

The electronic device according to clause 7 or 15, wherein the insulating layer is rectangular, as viewed in the thickness direction,
the conductive portion includes a plurality of the terminal portions,
the plurality of the terminal portions include a plurality of corner terminal portions disposed at each of the four corners of the insulating layer, and
the columnar portion is electrically connected to at least one of the plurality of corner terminal portions.

Clause 17.

The electronic device according to clause 4, wherein the metal layer contains copper.

Clause 18.

The electronic device according to clause 1, wherein the conductive portion contains copper.

Clause 19.

A method of manufacturing an electronic device comprising:
preparing a substrate including an insulating layer and a conductive portion;
forming a columnar portion having electrical conductivity so as to project from the conductive portion toward a first side in a thickness direction;
mounting an electronic element on the substrate; and
forming a sealing resin so as to cover the electronic element and the columnar portion.

Clause 20.

A method of manufacturing an electronic device, comprising:
preparing a substrate including an insulating layer and a conductive portion;
mounting an electronic element on a first side in a thickness direction of the substrate;
forming a sealing resin so as to cover the electronic element;
partially removing the sealing resin so as to form a recess opening toward the first side in the thickness direction and reaching the conductive portion; and
filling the recess with a conductor so as to form a columnar portion projecting from the conductive portion toward the first side in the thickness direction.

Clause 21.

The method according to clause 20, wherein, in forming the recess, the recess is formed so as to extend across the electronic element and the sealing resin by removing a part of the sealing resin and a part of the electronic element, and
in forming the columnar portion, the recess is filled with the conductor such that the conductor is in contact with the sealing resin and the electronic element.

1. An electronic device comprising:
a substrate including:
an insulating layer having an insulating layer obverse surface facing a first side in a thickness direction and an insulating layer reverse surface facing a second side opposite to the first side in the thickness direction, and
a conductive portion exposed from the insulating layer obverse surface and from the insulating layer reverse surface;
an electronic element including:
an element body having an element obverse surface facing the insulating layer obverse surface in the thickness direction, and
a plurality of electrodes disposed on the element obverse surface, the plurality of electrodes being electrically bonded to the conductive portion;
a columnar portion projecting from the conductive portion toward the first side in the thickness direction and having electrical conductivity; and
a sealing resin covering the insulating layer obverse surface, the electronic element, and the columnar portion.

2. The electronic device according to claim 1, wherein the element body has an element reverse surface facing the first side in the thickness direction, and,
the columnar portion extends beyond the element reverse surface toward the first side in the thickness direction.

3. The electronic device according to claim 1, wherein the columnar portion has a columnar portion side surface extending in the thickness direction,
the element body has an element side surface extending in the thickness direction, and
the columnar portion side surface and the element side surface are in contact with each other at least in part.

4. The electronic device according to claim 1, wherein the element body has an element reverse surface facing the first side in the thickness direction, and
the electronic element includes a metal layer disposed on the element reverse surface.

5. The electronic device according to claim 4, wherein the metal layer is connected to the columnar portion.

6. The electronic device according to claim 4, further comprising an insulating film laminated toward the first side in the thickness direction with respect to the metal layer.

7. The electronic device according to claim 1, wherein the conductive portion includes:
a terminal portion having a terminal reverse surface exposed from the insulating layer reverse surface, and
a wiring portion exposed from the insulating layer obverse surface and connecting the terminal portion and at least one of the plurality of electrodes.

8. The electronic device according to claim 7, wherein at least a part of the electronic element overlaps with the terminal portion, as viewed in the thickness direction.

9. The electronic device according to claim 7, wherein a metal film is provided on at least a part of the terminal portion.

10. The electronic device according to claim 7, wherein the columnar portion includes a tapered portion connected to the wiring portion, and
the tapered portion has a cross-section orthogonal to the thickness direction decreasing in size from the first side toward the second side in the thickness direction.

11. The electronic device according to claim 4, wherein the metal layer has an uneven portion on the first side in the thickness direction.

12. The electronic device according to claim 11, wherein the uneven portion has a plurality of protrusions arranged in a first direction orthogonal to the thickness direction, as viewed in the thickness direction.

13. The electronic device according to claim 11, wherein the plurality of protrusions are arranged in a matrix pattern, as viewed in the thickness direction.

14. The electronic device according to claim 11, wherein the uneven portion has a thickness in a range of 3 μm to 100 μm.

15. The electronic device according to claim 7, wherein the conductive portion includes a plurality of the terminal portions, the plurality of the terminal portions including a ground terminal portion for ground connection, and the columnar portion is electrically connected to the ground terminal portion.

16. The electronic device according to claim 15, wherein the insulating layer is rectangular, as viewed in the thickness direction,
the conductive portion includes a plurality of the terminal portions,
the plurality of the terminal portions include a plurality of corner terminal portions disposed at each of the four corners of the insulating layer, and
the columnar portion is electrically connected to at least one of the plurality of corner terminal portions.

17. The electronic device according to claim 4, wherein the metal layer contains copper.

18. The electronic device according to claim 1, wherein the conductive portion contains copper.

19. A method of manufacturing an electronic device comprising:
preparing a substrate including an insulating layer and a conductive portion;
forming a columnar portion having electrical conductivity so as to project from the conductive portion toward a first side in a thickness direction;
mounting an electronic element on the substrate; and
forming a sealing resin so as to cover the electronic element and the columnar portion.

20. A method of manufacturing an electronic device, comprising:
preparing a substrate including an insulating layer and a conductive portion;
mounting an electronic element on a first side in a thickness direction of the substrate;
forming a sealing resin so as to cover the electronic element;
partially removing the sealing resin so as to form a recess opening toward the first side in the thickness direction and reaching the conductive portion; and
filling the recess with a conductor so as to form a columnar portion projecting from the conductive portion toward the first side in the thickness direction.
